(19) United States
(12) Patent Application Publication
(10) Pub. No.: US 2024/0201609 A1
(43) Pub. Date: Jun. 20, 2024

(54) ELECTROPHOTOGRAPHIC PHOTOSENSITIVE MEMBER, PROCESS CARTRIDGE AND ELECTROPHOTOGRAPHIC APPARATUS

(71) Applicant: CANON KABUSHIKI KAISHA, Tokyo (JP)

(72) Inventors: YUKA ISHIDUKA, Shizuoka (JP); FUMIYUKI HIYAMA, Shizuoka (JP); AKIRA SAKAKIBARA, Shizuoka (JP); TSUTOMU NISHIDA, Shizuoka (JP); DAISUKE MIURA, Tokyo (JP)

(21) Appl. No.: 18/505,369

(22) Filed: Nov. 9, 2023

(30) Foreign Application Priority Data
Nov. 25, 2022 (JP) 2022-188615

(51) Int. Cl. G03G 5/147; C08G 63/193; G03G 21/18

(52) U.S. Cl. CPC G03G 5/14752; C08G 63/193; G03G 5/14756; G03G 21/1814

(57) ABSTRACT

Provided is an electrophotographic photosensitive member in which streaky image damage can be suppressed throughout long-term use in a low-temperature and low-humidity environment. An electrophotographic photosensitive member having a surface layer comprising a polyarylate and a polycarbonate, wherein the polyarylate has at least one structural unit selected from the group consisting of a structural unit represented by the following formula (1-1), a structural unit represented by the following formula (1-2) and a structural unit represented by the following formula (1-3), and the polycarbonate has a structural unit represented by the following formula (2-1).

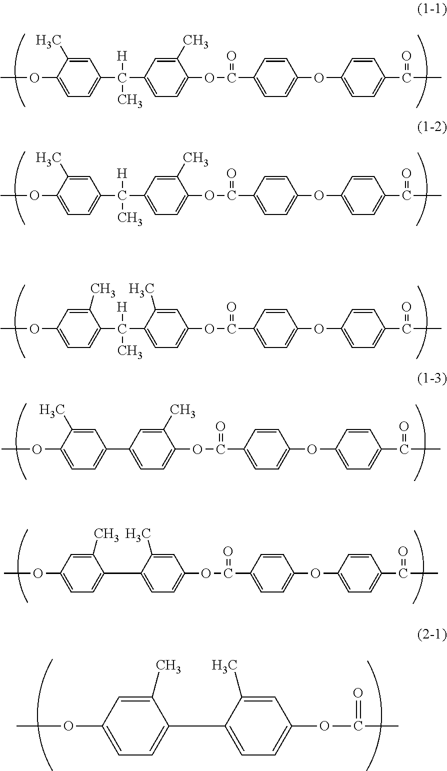

### BACKGROUND OF THE INVENTION

### Field of the Invention

The present disclosure relates to an electrophotographic photosensitive member, a process cartridge and an electrophotographic apparatus.

### Description of the Related Art

For electrophotographic photosensitive members, process cartridges and electrophotographic apparatuses, a wide range of studies have been thus far conducted for image quality improvement at the time of long-term use.

As an example, Japanese Patent No. 04862663 describes that an electrophotographic photosensitive member (hereinafter, also referred to as “photosensitive member”) containing a polyarylate having a specific skeleton and a polycarbonate in a photosensitive layer is capable of improving wear resistance and scratch resistance with respect to a load on the photosensitive member. However, fine projections and recesses are formed on the surface, which is inferred to be because the two resins in the layer are difficult to be uniformly dispersed. This structure is inferred to function to decrease the contact surface with an external substance.

### SUMMARY OF THE INVENTION

However, as a result of using the photosensitive member described in Japanese Patent No. 04862663 for a long time in a low-temperature and low-humidity environment by the inventors, streaky image damage attributed to scratches was generated. Regarding a cause thereof, it was found that, in a worn portion of a contact member with the surface layer of the photosensitive member, an external additive, paper powder or other hard foreign matter that is contained in toner is caught by the contact member and scratches are generated therefrom as a starting point. As the reason for this phenomenon to be observed in a low-temperature and low-humidity environment, the contact member itself becoming hard due to an influence of a low temperature is considered as one cause.

Therefore, the inventors paid attention to resins configuring the surface layer of the electrophotographic photosensitive member, consequently found that the use of a surface layer in which a polyarylate having a specific structure and a polycarbonate have been mixed together improves scratch resistance to external impacts and reached the present invention.

Therefore, an objective of the present invention is to provide an electrophotographic photosensitive member, a process cartridge and an electrophotographic apparatus in which a resin having high scratch resistance to external impacts is selected and image damage is suppressed.

The above-described objective is achieved by the present invention below. That is, a first aspect of the present invention is an electrophotographic photosensitive member having a surface layer comprising a polyarylate and a polycarbonate, wherein the polyarylate has at least one structural unit selected from the group consisting of a structural unit represented by the following formula (1-1), a structural unit represented by the following formula (1-2) and a structural unit represented by the following formula (1-3), and the polycarbonate has a structural unit represented by the following formula (2-1).

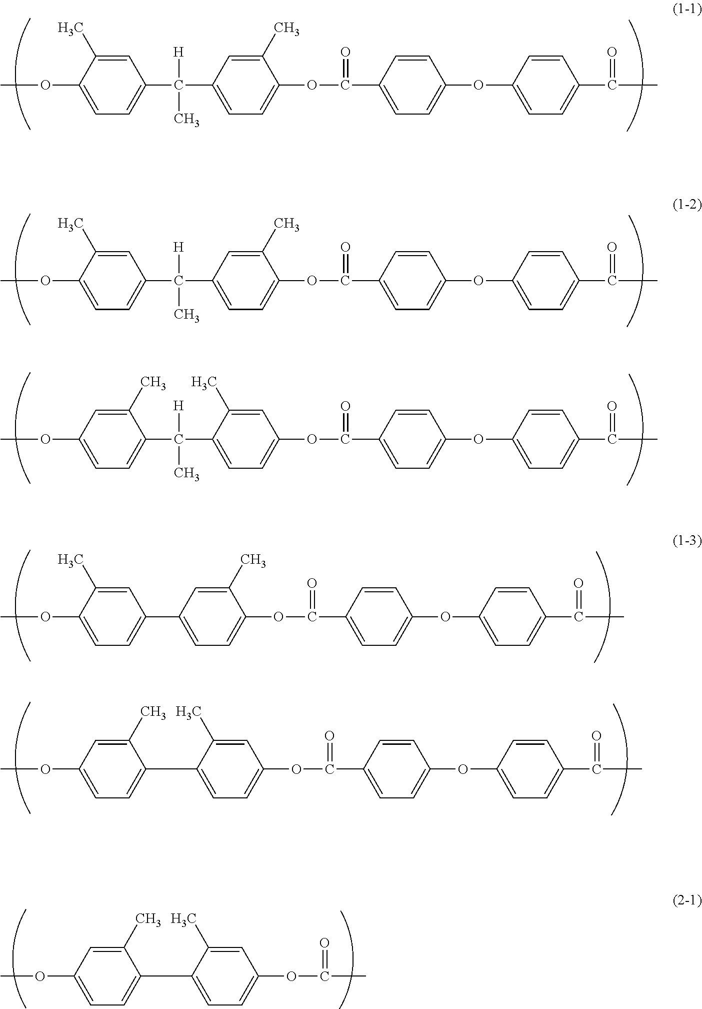

In addition, a second aspect is an electrophotographic photosensitive member having a surface layer comprising a polyarylate and a polycarbonate, wherein, in a component analysis of a polymer component collected from the surface layer, the polyarylate has a peak for which TIC has an MS spectrum where components with m/z=242 and m/z=227 are detected in pyrolysis gas chromatography-mass spectrometry under the coexistence of TMAH and has peaks at 2.40±0.02 ppm and 2.35±0.02 ppm in a ¹H-NMR spectrum for which heavy chloroform is used, and the polycarbonate has a peak for which TIC has an MS spectrum where components with m/z=242 and m/z=227 are detected in pyrolysis gas chromatography-mass spectrometry under the coexistence of TMAH and has a peak at 2.40±0.02 ppm in a ¹H-NMR spectrum for which heavy chloroform is used.

In addition, a process cartridge according to the present invention is a process cartridge that integrally supports the electrophotographic photosensitive member and at least one unit selected from the group consisting of a charging unit and a developing unit and is attachable to and detachable from a main body of an electrophotographic apparatus.

In addition, the present invention is an electrophotographic apparatus having the electrophotographic photosensitive member, a charging unit, an exposure unit, a developing unit and a transfer unit.

Further features of the present invention will become apparent from the following description of exemplary embodiments with reference to the attached drawings.

### BRIEF DESCRIPTION OF THE DRAWINGS

FIG. 1 is a view illustrating an example of the layer configuration of an electrophotographic photosensitive member according to the present invention.

FIG. 2 illustrates an example of the schematic configuration of an electrophotographic apparatus and a process cartridge of the present invention.

### DESCRIPTION OF THE EMBODIMENTS

Preferred embodiments of the present invention will now be described in detail in accordance with the accompanying drawings.

Hereinafter, the present disclosure will be described in detail with a preferable embodiment.

In a first aspect of the present invention, a polyarylate has at least one structural unit selected from the group consisting of a structural unit represented by the formula (1-1), a structural unit represented by the formula (1-2) and a structural unit represented by the formula (1-3), and a polycarbonate has a structural unit represented by the following formula (2-1), whereby the scratch resistance of a surface layer improves.

The inventors presume a reason therefor as described below.

Ordinarily, during printing, a hard foreign matter is caught between the surface layer of a photosensitive member and a contact member such as paper or a member in contact with the surface layer, the surface layer receives an external impact, and scratches are formed. Regarding how to receive the external impact at this time, there are two actions. The first one is an action in which the surface of the surface layer is slowly worn by the external impact in the parallel direction to the surface layer, whereby a scratch is formed, and the second one is an action in which a hole is instantly generated by the external impact in the perpendicular direction and grows, whereby a scratch is formed.

The polyarylate according to the present invention is stronger than the polycarbonate according to the present invention in terms of the scratch resistance to wear in the parallel direction, but is weaker than the polycarbonate according to the present invention in terms of the impact in the perpendicular direction. On the other hand, the polycarbonate of the present invention is weaker than the polyarylate according to the present invention in terms of the scratch resistance to wear in the parallel direction, but is stronger than the polyarylate according to the present invention in terms of the impact in the perpendicular direction. Furthermore, it is presumed that an electrophotographic photosensitive member of the present invention comprises a polyarylate and a polycarbonate according to the present invention in the surface layer, whereby entanglement between the resins is enhanced, external impacts can be absorbed, and the scratch resistance is further enhanced due to the action of a methyl group attached to an aromatic ring. Therefore, generally, it is presumed that the surface layer becomes strong with respect to external impacts and exhibits high scratch resistance.

Next, an electrophotographic photosensitive member according to one aspect of the present disclosure will be specifically described.

### Electrophotographic Photosensitive Member

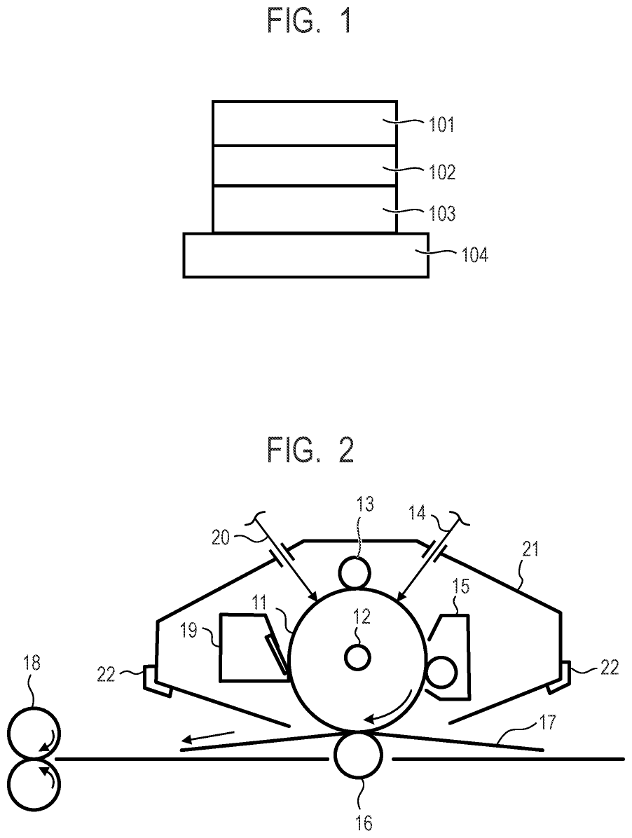

The electrophotographic photosensitive member of the present invention has a surface layer. FIG. 1 is a view illustrating an example of the layer configuration of the electrophotographic photosensitive member. In FIG. 1, an undercoat layer 103, a charge generation layer 102 and a charge transport layer (surface layer) 101 are laminated in this order on a support 104.

Examples of a method for producing the electrophotographic photosensitive member include a method in which a coating liquid for each layer, which will be described below, is prepared, applied in a desired layer order and dried. At this time, examples of a method for applying the coating liquid include dip coating, spray coating, inkjet coating, roll coating, die coating, blade coating, curtain coating, wire bar coating and ring coating. Among these, dip coating is preferable from the viewpoint of efficiency and productivity.

Hereinafter, each layer will be described.

### Support

The support is preferably a conductive support. In addition, examples of the shape of the support include a cylindrical shape, a belt shape and a sheet shape. Among these, a cylindrical support is preferable. In addition, on the outer surface of the support, a blasting treatment or a cutting treatment in which an electrochemical treatment such as anodization is performed to produce an oxide film may be performed. As the material of the support, a metal, a resin or glass is preferable.

Examples of the metal include aluminum, iron, nickel, copper, gold, stainless steel and alloys thereof. Among these, an aluminum support for which aluminum is used is preferable, and an aluminum alloy having an oxide film on the outer surface is more preferable. The oxide film is capable of suppressing the injection of charges from the support, and thus the stability of charging is high.

In addition, conductivity may be imparted by a treatment in which the resin or glass is mixed with or coated with a conductive material or the like.

### Conductive Layer

A conductive layer may be provided on the support. The conductive layer provided enables scratches or projections and recesses on the surface of the support to be hidden or the reflection of light on the surface of the support to be controlled.

The conductive layer preferably contains a conductive particle and a resin.

Examples of a material of the conductive particle include a metal oxide, a metal and carbon black.

Examples of the metal oxide include zinc oxide, aluminum oxide, indium oxide, silicon oxide, zirconium oxide, tin oxide, titanium oxide, magnesium oxide, antimony oxide and bismuth oxide. Examples of the metal include aluminum, nickel, iron, chromium, copper, zinc and silver.

Among these, as the conductive particle, the metal oxides are preferably used, and, particularly, titanium oxide, tin oxide and zinc oxide are more preferably used.

In a case where the metal oxide is used as the conductive particle, the surface of the metal oxide may be treated with a silane coupling agent or the like or an element such as phosphorus or aluminum or an oxide thereof may be doped into the metal oxide.

In addition, the conductive particle may be provided with a laminate configuration having a core particle and a coating layer that coats the particle. Examples of the core particle include titanium oxide, barium sulfate and zinc oxide. Examples of the coating layer include metal oxides such as tin oxide.

In addition, in a case where the metal oxide is used as the conductive particle, the volume-average particle diameter thereof is preferably 1 nm to 500 nm and more preferably 3 nm to 400 nm.

Examples of the resin include a polyvinyl acetal resin, an acrylic resin, a silicone resin, an epoxy resin, a melamine resin, a polyurethane resin, a phenolic resin and an alkyd resin.

In addition, the conductive layer may further contain a masking agent such as silicone oil, a resin particle or titanium oxide or the like.

The average film thickness of the conductive layer is preferably 1 μm to 50 μm and particularly preferably 3 μm to 40 μm.

The conductive layer can be formed by preparing a coating liquid for the conductive layer containing each of the above-described materials and a solvent and forming and drying a coating film thereof. Examples of the solvent that is used in the coating liquid include an alcoholic solvent, a sulfoxide-based solvent, a ketone-based solvent, an ether-based solvent, an ester-based solvent and an aromatic hydrocarbon-based solvent. Examples of a dispersion method for dispersing the conductive particle in the coating liquid for the conductive layer include methods in which a paint shaker, a sand mill, a ball mill or a liquid collision-type high speed disperser is used.

### Undercoat Layer

An undercoat layer may be provided on the support or the conductive layer. The undercoat layer provided enables the adhesion function between layers to be enhanced or a charge injection-preventing function to be imparted.

The undercoat layer preferably contains a resin. In addition, the undercoat layer may be formed as a cured film by polymerizing a composition containing a monomer having a polymerizable functional group.

Examples of the resin include a polyvinyl acetal resin, an acrylic resin, an epoxy resin, a melamine resin, a polyurethane resin, a phenol resin, a polyvinylphenol resin, an alkyd resin, a polyvinyl alcohol resin, a polyethylene oxide resin, a polypropylene oxide resin, a polyamide resin, a polyamide acid resin, a polyimide resin, a polyamideimide resin and a cellulose resin.

Examples of the polymerizable functional group in the monomer having a polymerizable functional group include an isocyanate group, a blocked isocyanate group, a methylol group, an alkylated methylol group, an epoxy group, a metal alkoxide group, a hydroxyl group, an amino group, a carboxyl group, a thiol group, a carboxylic acid anhydride group and a carbon-carbon double bond group.

In addition, the undercoat layer may further contain an electron transport substance, a metal oxide, a metal or a conductive polymer for the purpose of enhancing electrical properties. Among these, an electron transport substance and a metal oxide are preferably used.

Examples of the electron transport substance include a quinon compound, an imide compound, a benzimidazole compound, a cyclopentadienylidene compound, a fluorenone compound, a xanthone compound, a benzophenone compound, a cyanovinyl compound, a halogenated aryl compound, a silole compound and a boron-containing compound. The undercoat layer may be formed as a cured film by using an electron transport substance having a polymerizable functional group as the electron transport substance and copolymerizing the electron transport substance with a monomer having the above-described polymerizable functional group.

Examples of the metal oxide include indium tin oxide, tin oxide, indium oxide, titanium oxide, zinc oxide, aluminum oxide and silicon dioxide. Examples of the metal include gold, silver and aluminum.

In addition, the undercoat layer may further contain an additive.

The average film thickness of the undercoat layer is preferably 0.1 μm to 50 μm, more preferably 0.2 μm to 40 μm and particularly preferably 0.3 μm to 30 μm.

The undercoat layer can be formed by preparing a coating liquid for the undercoat layer containing each of the above-described materials and a solvent and forming, drying and/or curing a coating film thereof. Examples of the solvent that is used in the coating liquid include an alcoholic solvent, a ketone-based solvent, an ether-based solvent, an ester-based solvent and an aromatic hydrocarbon-based solvent.

### Photosensitive Layer

A photosensitive layer of the electrophotographic photosensitive member is provided on the support, the conductive layer or the undercoat layer and is mainly classified into (1) a laminated photosensitive layer and (2) a single-layer photosensitive layer. (1) The laminated photosensitive layer has a charge generation layer containing a charge-generating substance and a charge transport layer containing a charge transport substance. (2) The single-layer photosensitive layer has a photosensitive layer containing a charge-generating substance and a charge transport substance together.

### (1) Laminated Photosensitive Layer

The laminated photosensitive layer has a charge generation layer and a charge transport layer.

### (1-1) Charge Generation Layer

The charge generation layer preferably contains a charge-generating substance and a resin.

Examples of the charge-generating substance include an azo pigment, a perylene pigment, a polycyclic quinone pigment, an indigo pigment and a phthalocyanine pigment. Among these, an azo pigment and a phthalocyanine pigment are preferable. Among the phthalocyanine pigments, an oxytitanium phthalocyanine pigment, a chlorogallium phthalocyanine pigment and a hydroxygallium phthalocyanine pigment are preferable.

The content of the charge-generating substance in the charge generation layer is preferably 40% by mass to 85% by mass and more preferably 60% by mass to 80% by mass with respect to the total mass of the charge generation layer.

Examples of the resin include a polyarylate, a polycarbonate, a polyvinyl acetal resin, a polyvinyl butyral resin, an acrylic resin, a silicone resin, an epoxy resin, a melamine resin, a polyurethane resin, a phenolic resin, a polyvinyl alcohol resin, a cellulose resin, a polystyrene resin, a polyvinyl acetate resin and a polyvinyl chloride resin. Among these, a polyvinyl butyral resin is more preferable.

In addition, the charge generation layer may further contain an additive such as an antioxidant or an ultraviolet absorber. Specific examples include a hindered phenol compound, a hindered amine compound, a sulfur compound, a phosphorus compound and a benzophenone compound.

The average film thickness of the charge generation layer is preferably 0.1 μm to 0.8 μm and more preferably 0.15 μm to 0.4 μm.

The charge generation layer can be formed by preparing a coating liquid for the charge generation layer containing each of the above-described materials and a solvent and forming and drying a coating film thereof. Examples of the solvent that is used in the coating liquid include an alcoholic solvent, a sulfoxide-based solvent, a ketone-based solvent, an ether-based solvent, an ester-based solvent and an aromatic hydrocarbon-based solvent.

### (1-2) Charge Transport Layer

The charge transport layer preferably contains a charge transport substance and a resin.

Examples of the charge transport substance include a polycyclic aromatic compound, a heterocyclic compound, a hydrazone compound, a styryl compound, an enamine compound, a benzidine compound, a triarylamine compound and a resin having a group derived from these substances. Among these, a triarylamine compound and a benzidine compound are preferable since an effect of suppressing the generation of a bullet point is high.

Hereinafter, preferable charge transport substances will be shown.

TABLE 1

| | Structure |
|---|---|
| CTM1 | 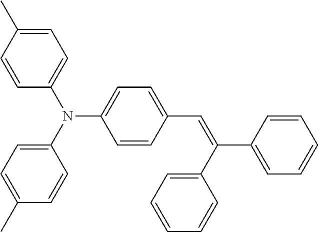 [SMILES: Cc1ccc(N(c2ccc(C)cc2)c2ccc(C=C(c3ccccc3)c3ccccc3)cc2)cc1] |
| CTM2 | 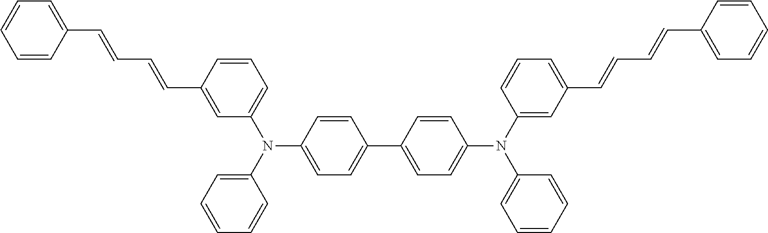 [SMILES: C(/C=C/c1cccc(N(c2ccccc2)c2ccc(-c3ccc(N(c4ccccc4)c4cccc(/C=C/C=C/c5ccccc5)c4)cc3)cc2)c1)=C\c1ccccc1] |
| CTM3 | 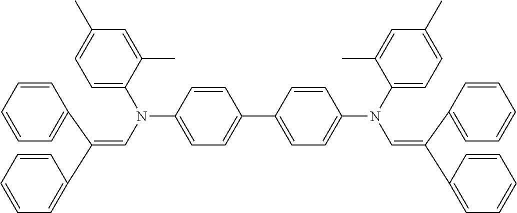 [SMILES: Cc1ccc(N(C=C(c2ccccc2)c2ccccc2)c2ccc(-c3ccc(N(C=C(c4ccccc4)c4ccccc4)c4ccc(C)cc4C)cc3)cc2)c(C)c1] |
| CTM4 | 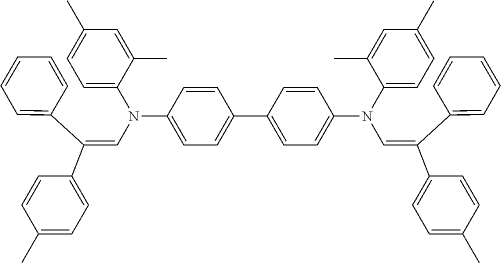 [SMILES: Cc1ccc(/C(=C/N(c2ccc(-c3ccc(N(/C=C(\c4ccccc4)c4ccc(C)cc4)c4ccc(C)cc4C)cc3)cc2)c2ccc(C)cc2C)c2ccccc2)cc1] |
| CTM5 | 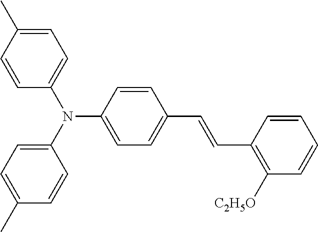 |
| CTM6 | 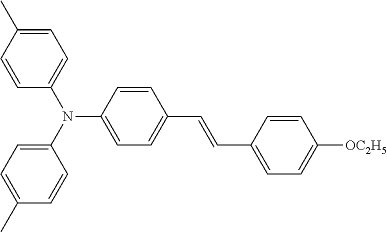 [SMILES: CCOc1ccc(/C=C/c2ccc(N(c3ccc(C)cc3)c3ccc(C)cc3)cc2)cc1] |
| CTM7 | 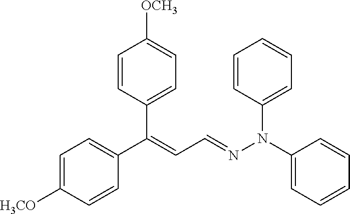 [SMILES: COc1ccc(C(=C/C=N/N(c2ccccc2)c2ccccc2)c2ccc(OC)cc2)cc1] |
| CTM8 | 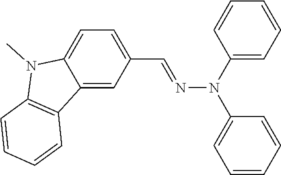 [SMILES: Cn1c2ccccc2c2cc(/C=N/N(c3ccccc3)c3ccccc3)ccc21] |
| CTM9 | 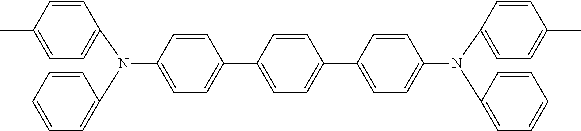 |
| CTM10 | 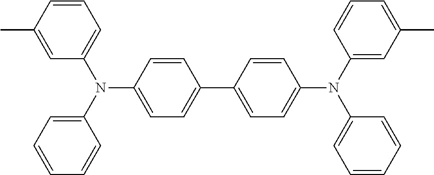 |

The content of the charge transport substance in the charge transport layer is preferably 25% by mass to 70% by mass and more preferably 30% by mass to 55% by mass with respect to the total mass of the charge transport layer.

Examples of the resin include a polyarylate, a polycarbonate, an acrylic resin and a polystyrene resin. In a case where the charge transport layer serves as the surface layer, the charge transport layer needs to contain, among these, a polyarylate and a polycarbonate having the structure according to the present invention from the viewpoint of scratch resistance.

Hereinafter, resins that are used in the first aspect of the present invention will be shown.

The polyarylate has at least one structural unit selected from the group consisting of a structural unit represented by the following formula (1-1), a structural unit represented by the following formula (1-2) and a structural unit represented by the following formula (1-3), and
the polycarbonate has a structural unit represented by the following formula (2-1).

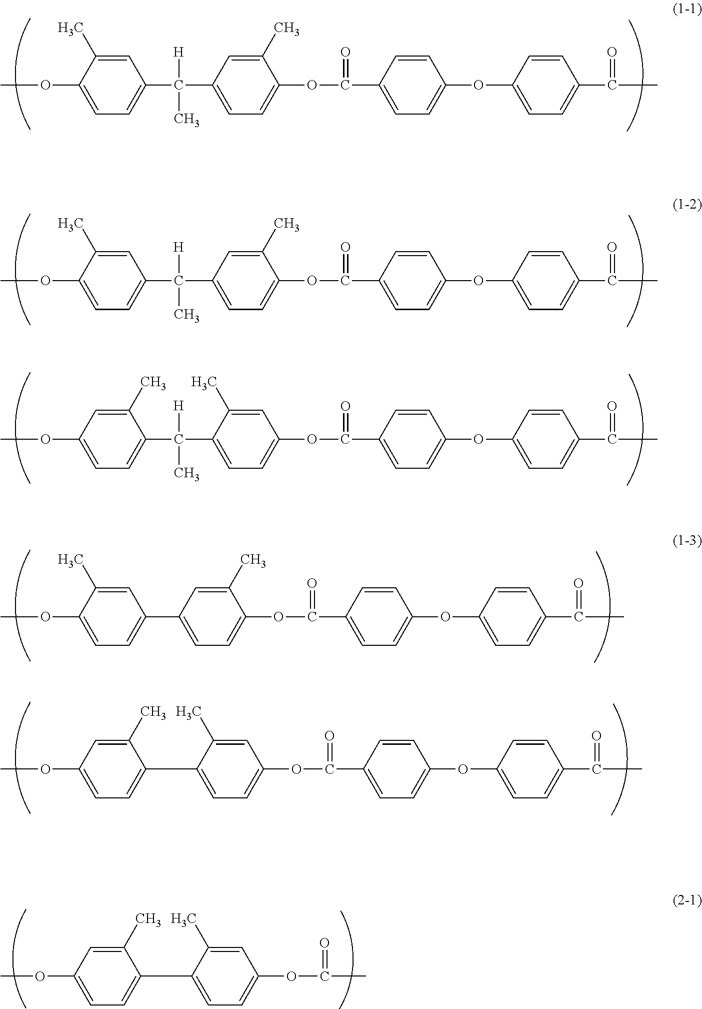

The surface layer according to the present invention preferably comprises 5 mol % to 40 mol % of the structural unit represented by the formula (2-1) from the viewpoint of scratch resistance, and entanglement between the resins increases to improve the scratch resistance.

Furthermore, the polycarbonate according to the present invention comprises 20 mol % to 60 mol % of the structural unit represented by the formula (2-1), whereby entanglement between the resins further increases to improve the scratch resistance.

In addition, a second aspect of the present invention is an electrophotographic photosensitive member having a surface layer comprising a polyarylate and a polycarbonate,
in which, in a component analysis of a polymer component collected from the surface layer,
the polyarylate
has a peak for which a total ion chromatogram (TIC) has an MS spectrum where components with m/z=242 and m/z=227 are detected in pyrolysis gas chromatography-mass spectrometry under the coexistence of tetramethylammonium hydroxide (TMAH) and
has peaks at 2.40±0.02 ppm and 2.35±0.02 ppm in a ¹H-NMR spectrum for which heavy chloroform is used, and
the polycarbonate
has a peak for which TIC has an MS spectrum where components with m/z=242 and m/z=227 are detected in pyrolysis gas chromatography-mass spectrometry under the coexistence of TMAH and
has a peak at 2.40±0.02 ppm in a ¹H-NMR spectrum for which heavy chloroform is used.

Having a peak for which the total ion chromatogram (TIC) has an MS spectrum where components with m/z=242 and m/z=227 are detected and having a peak at 2.40±0.02 ppm in a ¹H-NMR spectrum for which heavy chloroform is used indicate having the structural unit represented by the formula (2-1).

In addition, having a peak for which the total ion chromatogram (TIC) has an MS spectrum where components with m/z=242 and m/z=227 are detected and having a peak at 2.35±0.02 ppm in a ¹H-NMR spectrum for which heavy chloroform is used indicate having the structural unit represented by the following formula (2-2).

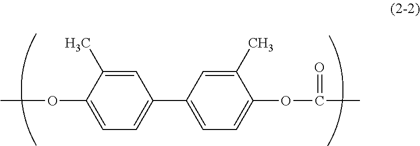

Therefore, in the case of having the above-described spectrums, it is indicated that the polyarylate has at least the structures of the formula (2-1) and formula (2-2), and it is indicated that the polycarbonate has at least the structure of the formula (2-1).

Even in a case where the surface layer of the photosensitive member of the present invention contains a polyarylate represented by a formula (1-3), the above-described spectra are exhibited, and thus a spectrum in which both the polyarylate and the polycarbonate are mixed is shown.

The electrophotographic photosensitive member has the surface layer comprising the polyarylate and the polycarbonate, and the polyarylate and the polycarbonate have the above-described intrinsic spectra, whereby the scratch resistance of the surface layer improves. It is presumed that the polyarylate has the structural part of the formula (2-1) and a structural part similar thereto as a skeleton, and the polycarbonate has the structural part of the formula (2-1), which is common, whereby entanglement of the resins is enhanced, external impacts can be absorbed, and the scratch resistance is further enhanced.

Specific analysis methods of the surface layer will be described below.

### Reprecipitation of Resins in Photosensitive Member Surface Layer

To cut photosensitive member
   The photoreceptor is cut using a fretsaw at a position 10 cm apart from an end portion in the generatrix direction.
To wash drum inner surface of 10 cm cut-out part
   The cylinder inner surface is wiped off using silbon paper soaked with chloroform.
To elute surface layer
   A 3 cm part of the drum end portion on the cut side is immersed in chloroform.
   (Approximately 60 cc of chloroform is poured into a 100 mL beaker, and the part is immersed therein for five minutes at room temperature.)
To concentrate (concentrated liquefaction)
   Concentration is performed with a rotary evaporator and stopped after the part is concentrated up to 2 mL.
To reprecipitate
   50 mL of a methanol/acetone liquid mixture (volume ratio=1:1) is prepared, and the full amount of the concentrated liquid is added dropwise while being stirred.
To filter
   Suction filtration is performed with a Hirsch funnel.
   (Funnel: SU-40, filter paper: No. 5C-40, all manufactured by Kiriyama Glass Works Co.)
To dry
   A residue on the filter paper is collected with a spatula and dried in a vacuum (at 70° C. for one hour).

### Pyrolysis GCMS

Apparatus configuration: Pyrolysis apparatus+gas chromatography (GC) apparatus+mass spectrometry (MS) apparatus
Pyrolysis apparatus: JPS-700 manufactured by Japan Analytical Industry Co., Ltd.
GC apparatus: FOCUS-GC manufactured by Thermo Fisher Scientific, Inc.
MS apparatus: ISQ manufactured by Thermo Fisher Scientific, Inc.
Sample amount: 0.1 mg (TMAH (manufactured by Tama Chemicals Co., Ltd.) is contained)
Pyrolysis temperature: 590° C. (PYROFOIL F590 manufactured by Japan Analytical Industry Co., Ltd. is used)
Column: “HP5-MS” (19091S-433 manufactured by Agilent Technologies International Japan, Ltd., length: 30 m, inner diameter: 0.25 mm, film thickness: 0.25 μm)
GC inlet conditions:
   Inlet temp.: 250° C.
   Split flow: 50 mL/min
GC temperature rise conditions: 40° C. (5 min)→10° C./min (300° C.)→300° C. (20 min)
MS conditions:
   Ion source temp.: 200° C.
   MS transfer line temp.: 250° C.

### NMR Measurement

Measurement sample preparation
20 mg of a sample is dissolved in 1 g of heavy chloroform containing tetramethylsilane, which is a standard substance, and the full amount is moved to an NMR tube.
(Heavy chloroform: Manufactured by Sigma-Aldrich, Japan, chloroform-d, model No.: 612200)
(NMR tube: Manufactured by NORELL, Inc., ST500-7, model No.: S3010)
NMR measurement
Apparatus: Manufactured by Bruker, AVANCE 500
Conditions: Proton NMR, automatic measurement by ICON-NMR
Cumulated number: 32 times
Standard peak: The methyl group peak of tetramethylsilane is set to 0 ppm.

### Fractionation of Polyarylate and Polycarbonate

The resins are fractionated from the component in which the resins in the photosensitive member surface layer have been reprecipitated with a fractionation apparatus capable of separating and collecting the component such as size exclusion chromatography or high performance liquid chromatography.

The content ratio between the charge transport substance and the resin is preferably 4:10 to 20:10 and more preferably 5:10 to 10:10 in terms of mass ratio.

In addition, the charge transport layer may contain an additive such as an antioxidant, an ultraviolet absorber, a plasticizer, a leveling agent, a lubrication agent or a wear resistance improver.

Specific examples thereof include a hindered phenol compound, a hindered amine compound, a sulfur compound, a phosphorus compound, a benzophenone compound, a siloxane-modified resin, silicone oil, a fluororesin fine particle, a polystyrene resin particle, a polyethylene resin particle, a silica fine particle, an alumina fine particle and a boron nitride fine particle. Among these, a silica fine particle is preferable from the viewpoint of scratch resistance, and, when the volume-average particle diameter is 0.1 μm to 0.5 μm, it is easy to absorb external impacts, and scratches can be suppressed in the charge transport layer of the present invention.

The average film thickness of the charge transport layer is preferably 5 μm to 50 μm, more preferably 8 μm to 40 μm and particularly preferably 10 μm to 30 μm.

The charge transport layer can be formed by preparing a coating liquid for the charge transport layer containing each of the above-described materials and a solvent and forming and drying a coating film thereof. Examples of the solvent that is used in the coating liquid include an alcoholic solvent, a ketone-based solvent, an ether-based solvent, an ester-based solvent and an aromatic hydrocarbon-based solvent. Among these solvents, the ether-based solvent or the aromatic hydrocarbon-based solvent is preferable.

### Volume-Average Particle Diameter

A method for measuring the volume-average particle diameter of the particle is as described below.

The particle is separated from the layer, 100 silica primary particles are observed with a scanning electron microscope (SEM) at a magnification of 100,000 times, the longest diameter and shortest diameter of each primary particle are measured, and a spherical equivalent diameter is measured from the middle value thereof. A 50% diameter (D50v) in the cumulative frequency of the obtained spherical equivalent diameters was obtained and regarded as the volume-average particle diameter of the particles.

### (2) Single-Layer Photosensitive Layer

The single-layer photosensitive layer can be formed by preparing a coating liquid for a photosensitive layer containing a charge-generating substance, a charge transport substance, a resin and a solvent and forming and drying a coating film thereof. The charge-generating substance, the charge transport substance and the resin are the same as the materials exemplified in the “(1) Laminated Photosensitive Layer” section.

### Protective Layer

In a case where a protective layer is the surface layer, the protective layer contains the resin according to the present invention.

The protective layer may contain an additive such as an antioxidant, an ultraviolet absorber, a plasticizer, a leveling agent, a lubrication agent, a scratch/wear resistance improver or a polymerization reaction initiator.

Specific examples thereof include a hindered phenol compound, a hindered amine compound, a sulfur compound, a phosphorus compound, a benzophenone compound, a siloxane-modified resin, silicone oil, a fluororesin fine particle, a polystyrene resin fine particle, a polyethylene resin fine particle, a silica fine particle, an alumina fine particle, a boron nitride fine particle, titanium oxide, zinc oxide, tin oxide and indium oxide. Among these, a silica fine particle is preferable from the viewpoint of scratch resistance, and, when the volume-average particle diameter is 0.1 μm to 0.5 μm, it is easy to absorb external impacts, and scratches can be suppressed in the protective layer of the present invention.

Furthermore, a siloxane resin or a charge transport substance can be added thereto. Examples of the charge transport substance include a triarylamine compound, a hydrazone compound, a stilbene compound, a pyrazoline compound, an oxazole compound, a thiazole compound and a triarylmethane compound. The average film thickness of the protective layer is preferably 0.5 μm to 10 μm and preferably 1 μm to 7 μm. At the time of applying the coating liquid for each of the above-described layers, an application method such as a dip coating method (dipping method), a spray coating method, a spinner coating method, a bead coating method, a blade coating method or a beam coating method can be used.

### Process Cartridge and Electrophotographic Apparatus

A process cartridge according to one aspect of the present disclosure integrally supports the electrophotographic photosensitive member, which has been thus far described, and at least one unit selected from the group consisting of a charging unit, a developing unit and a cleaning unit and is detachably attachable to an electrophotographic apparatus main body.

In addition, the electrophotographic apparatus according to one aspect of the present disclosure has a process cartridge having at least an electrophotographic photosensitive member and a charging member and at least one selected from the group consisting of an exposure unit, a developing unit and a transfer unit.

FIG. 2 illustrates an example of the schematic configuration of a process cartridge 21 and an electrophotographic apparatus having the process cartridge 21.

A cylindrical electrophotographic photosensitive member 11 is driven to rotate around a shaft 12 in an arrow direction at a predetermined peripheral velocity. The surface of the electrophotographic photosensitive member 11 is charged to a predetermined positive or negative potential with a charging unit 13. In the present embodiment, the charging unit 13 may adopt a roller charging method in which a roller-type charging member is used. The charged surface of the electrophotographic photosensitive member 11 is irradiated with exposure light 14 from an exposure unit (not illustrated), and an electrostatic latent image corresponding to target image information is formed. The electrostatic latent image formed on the surface of the electrophotographic photosensitive member 11 is developed by supplying toner accommodated in a developing unit 15, and a toner image is formed on the surface of the electrophotographic photosensitive member 11. The toner image formed on the surface of the electrophotographic photosensitive member 11 is transferred to a transfer material 17 with a transfer unit 16. The transfer material 17 to which the toner image has been transferred is conveyed to a fixing unit 18, subjected to a fixing treatment of the toner image and printed out to the outside of the electrophotographic apparatus. The electrophotographic apparatus may have a cleaning unit 19 for removing deposit such as the toner remaining on the surface of the electrophotographic photosensitive member 11 after the transfer. The cleaning unit is preferably a cleaning blade having an urethane resin. In addition, a so-called cleaner-less system in which no cleaning unit is separately provided and the deposit is removed with the developing unit or the like may also be used. The electrophotographic apparatus may have a neutralization mechanism that neutralizes the surface of the electrophotographic photosensitive member 11 with front exposure light 20 from a front exposure unit (not illustrated). In addition, a guiding unit 22 such as a rail may be provided to make the process cartridge 21 according to one aspect of the present disclosure attachable to and detachable from the electrophotographic apparatus main body.

The electrophotographic photosensitive member according to one aspect of the present disclosure can be used in laser beam printers, LED printers, copiers, facsimiles and multifunction printers thereof.

According to the present invention, an electrophotographic photosensitive member in which the surface layer of the electrophotographic photosensitive member has high scratch resistance and thus streaky image damage can be suppressed throughout long-term use in a low-temperature and low-humidity environment can be provided.

### EXAMPLES

Hereinafter, a process cartridge and an electrophotographic apparatus according to the present disclosure will be described in more detail using Examples and Comparative Examples. The present disclosure is not limited to configurations that are embodied by the following Examples. In the description of the following Examples, “parts” is mass-based unless particularly otherwise described.

### Production Example of Polyarylate A1

100.00 parts by mass of the following structural formula (B-1) as a divalent phenol component, 1.77 parts by mass of p-tert-butylphenol (PTBP) as a terminal blocking agent, 34.67 parts by mass of sodium hydroxide (NaOH) as an alkali, 1.04 parts by mass of a 50 mass % aqueous solution of tri-n-butylbenzylammonium chloride (TBBAC) as a polymerization catalyst and 0.50 parts by mass of sodium hydrosulfite as an antioxidant were charged into a reaction container including a stirring apparatus and dissolved in 3300 parts by mass of water (water phase). In addition, separately from this, 121.79 parts by mass of the following structural formula (B-2) was dissolved in 2600 parts by mass of methylene chloride (organic phase).

The mole ratios are as described below.

Structural formula (B-1):PTBP:structural formula (B-2):TBBAC:NaOH=100.00:2.86:100.00:0.68:210.00 (mole ratios).

The water phase was stirred in advance, the organic phase was added to the water phase under strong stirring, and polymerization was performed at 15° C. for two hours by an interfacial polymerization method. After that, the stirring was stopped, and the water phase and the organic phase were separated from each other by decantation. After the water phase was removed, 500 parts by mass of methylene chloride, 3000 parts by mass of pure water and 10 parts by mass of acetic acid were added thereto to stop the reaction, and stirring was performed at 15° C. for 30 minutes. After that, the organic phase was washed with pure water 10 times, and the organic phase was added to methanol to precipitate a polymer. The precipitated polymer was filtered and then dried at 150° C. in a vacuum for 24 hours, thereby obtaining a polyarylate A1. The viscosity-average molecular weight of the obtained polyarylate A1 was 47,000.

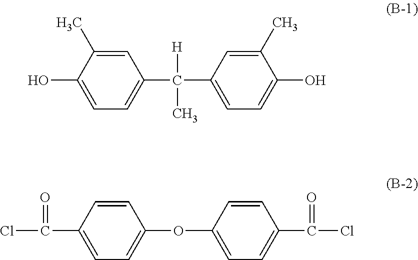 [SMILES: Cc1cc(C(C)c2ccc(O)c(C)c2)ccc1O ; O=C(Cl)c1ccc(Oc2ccc(C(=O)Cl)cc2)cc1]

### Production Example of Polyarylate A2

50.00 parts by mass of the structural formula (B-1) and 50.00 parts by mass of the following structural formula (B-3) as divalent phenol components, 1.77 parts by mass of p-tert-butylphenol (PTBP) as a terminal blocking agent, 34.67 parts by mass of sodium hydroxide (NaOH) as an alkali, 1.04 parts by mass of a 50 mass % aqueous solution of tri-n-butylbenzylammonium chloride (TBBAC) as a polymerization catalyst and 0.50 parts by mass of sodium hydrosulfite as an antioxidant were charged into a reaction container including a stirring apparatus and dissolved in 3300 parts by mass of water (water phase). In addition, separately from this, 121.79 parts by mass of the structural formula (B-2) was dissolved (organic phase).

The mole ratios are as described below.

Structural formula (B-1):structural formula (B-3):PTBP:structural formula (B-2):TBBAC:NaOH=50.00:50.00:2.86:100.00:0.68:210.00 (mole ratios).

The water phase was stirred in advance, the organic phase was added to the water phase under strong stirring, and polymerization was performed at 15° C. for two hours by an interfacial polymerization method. After that, the stirring was stopped, and the water phase and the organic phase were separated from each other by decantation. After the water phase was removed, 500 parts by mass of methylene chloride, 3000 parts by mass of pure water and 10 parts by mass of acetic acid were added thereto to stop the reaction, and stirring was performed at 15° C. for 30 minutes. After that, the organic phase was washed with pure water 10 times, and the organic phase was added to methanol to precipitate a polymer. The precipitated polymer was filtered and then dried at 150° C. in a vacuum for 24 hours, thereby obtaining a polyarylate A2.

The viscosity-average molecular weight of the obtained polyarylate A2 was 48,000.

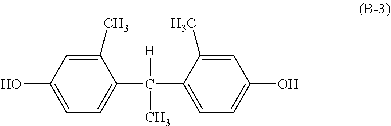 [SMILES: Cc1cc(O)ccc1C(C)c1ccc(O)cc1C]

### Production Examples of Polyarylates A3 to A14

Polyarylates were produced in the same manner as in the Production Example of the polyarylate A2 except that, in the Production Example of the polyarylate A2, structures (configuration units that are included in the structural units of the present invention) and rates were changed as shown in Table 2.

TABLE 2

| | Configuration unit 1 | |
|---|---|---|
| A1 | 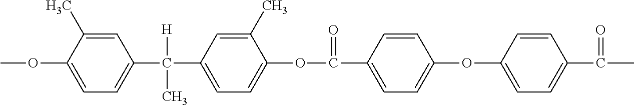 [SMILES: COc1ccc(C(C)c2ccc(OC(=O)c3ccc(Oc4ccc(C(C)=O)cc4)cc3)c(C)c2)cc1C] | |
| | — | |
| A2 | 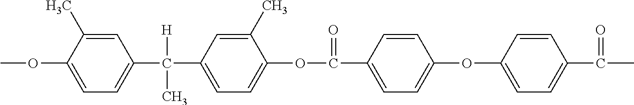 [SMILES: COc1ccc(C(C)c2ccc(OC(=O)c3ccc(Oc4ccc(C(C)=O)cc4)cc3)c(C)c2)cc1C] | |
| | 50 mol | |
| A3 | 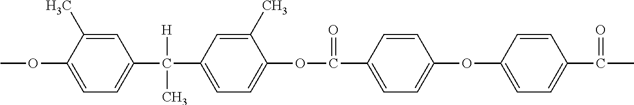 [SMILES: COc1ccc(C(C)c2ccc(OC(=O)c3ccc(Oc4ccc(C(C)=O)cc4)cc3)c(C)c2)cc1C] | |
| | 60 mol | |
| A4 | 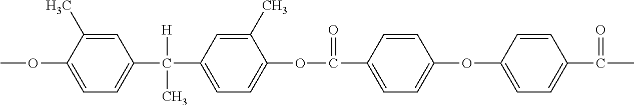 [SMILES: COc1ccc(C(C)c2ccc(OC(=O)c3ccc(Oc4ccc(C(C)=O)cc4)cc3)c(C)c2)cc1C] | |
| | 40 mol | |
| A5 | 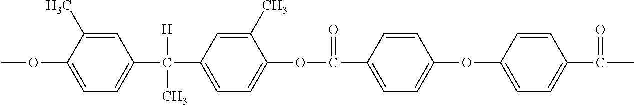 [SMILES: COc1ccc(C(C)c2ccc(OC(=O)c3ccc(Oc4ccc(C(C)=O)cc4)cc3)c(C)c2)cc1C] | |
| | 70 mol | |
| A6 | 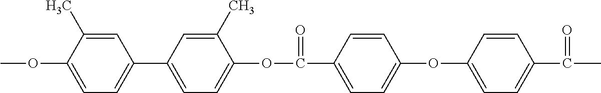 [SMILES: COc1ccc(-c2ccc(OC(=O)c3ccc(Oc4ccc(C(C)=O)cc4)cc3)c(C)c2)cc1C] | |
| | 50 mol | |
| A7 | 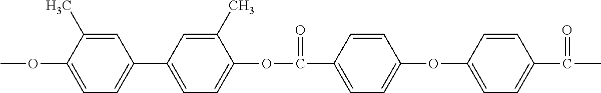 [SMILES: COc1ccc(-c2ccc(OC(=O)c3ccc(Oc4ccc(C(C)=O)cc4)cc3)c(C)c2)cc1C] | |
| | 60 mol | |
| A8 | 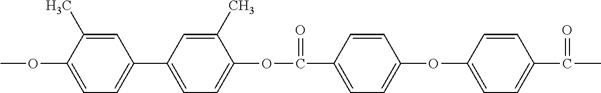 [SMILES: COc1ccc(-c2ccc(OC(=O)c3ccc(Oc4ccc(C(C)=O)cc4)cc3)c(C)c2)cc1C] | |
| | 40 mol | |
| A9 | 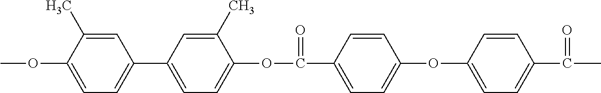 [SMILES: COc1ccc(-c2ccc(OC(=O)c3ccc(Oc4ccc(C(C)=O)cc4)cc3)c(C)c2)cc1C] | |
| | 20 mol | |
| A10 | 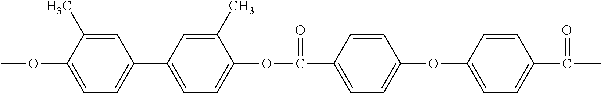 [SMILES: COc1ccc(-c2ccc(OC(=O)c3ccc(Oc4ccc(C(C)=O)cc4)cc3)c(C)c2)cc1C] | |
| | 30 mol | |
| A11 | 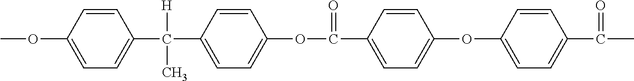 [SMILES: COc1ccc(C(C)c2ccc(OC(=O)c3ccc(Oc4ccc(C(C)=O)cc4)cc3)cc2)cc1] | |
| | — | |
| A12 | 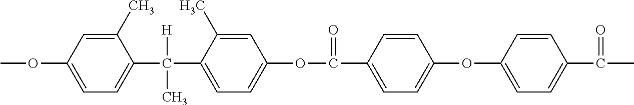 [SMILES: COc1ccc(C(C)c2ccc(OC(=O)c3ccc(Oc4ccc(C(C)=O)cc4)cc3)cc2C)c(C)c1] | |
| | — | |
| A13 | 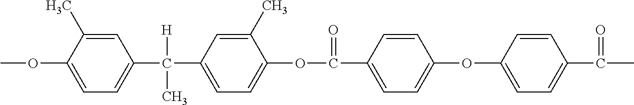 [SMILES: COc1ccc(C(C)c2ccc(OC(=O)c3ccc(Oc4ccc(C(C)=O)cc4)cc3)c(C)c2)cc1C] | |
| | 60 mol | |
| A14 | 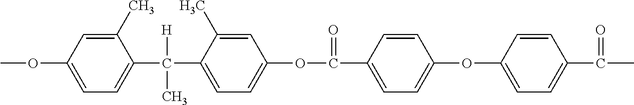 [SMILES: COc1ccc(C(C)c2ccc(OC(=O)c3ccc(Oc4ccc(C(C)=O)cc4)cc3)cc2C)c(C)c1] | |
| | 60 mol | |
| | | Molecular |
| | Configuration unit 2 | weight |
| A1 | | 47000 |
| | — | |
| A2 | 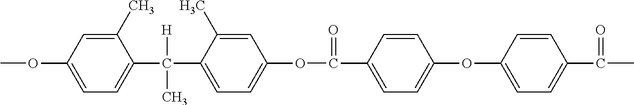 [SMILES: COc1ccc(C(C)c2ccc(OC(=O)c3ccc(Oc4ccc(C(C)=O)cc4)cc3)cc2C)c(C)c1] | 48000 |
| | 50 mol | |
| A3 | 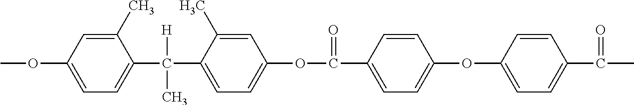 [SMILES: COc1ccc(C(C)c2ccc(OC(=O)c3ccc(Oc4ccc(C(C)=O)cc4)cc3)cc2C)c(C)c1] | 48000 |
| | 40 mol | |
| A4 | 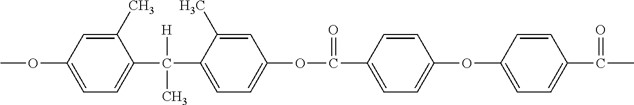 [SMILES: COc1ccc(C(C)c2ccc(OC(=O)c3ccc(Oc4ccc(C(C)=O)cc4)cc3)cc2C)c(C)c1] | 48000 |
| | 60 mol | |
| A5 | 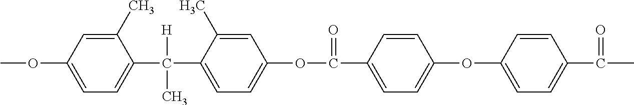 [SMILES: COc1ccc(C(C)c2ccc(OC(=O)c3ccc(Oc4ccc(C(C)=O)cc4)cc3)cc2C)c(C)c1] | 45000 |
| | 30 mol | |
| A6 | 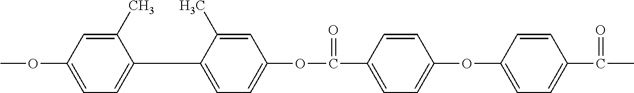 [SMILES: COc1ccc(Cc2ccc(OC(=O)c3ccc(Oc4ccc(C(C)=O)cc4)cc3)cc2C)c(C)c1] | 48000 |
| | 50 mol | |
| A7 | 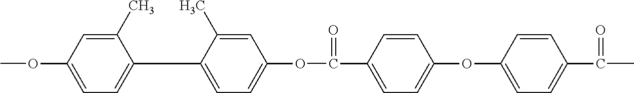 [SMILES: COc1ccc(Cc2ccc(OC(=O)c3ccc(Oc4ccc(C(C)=O)cc4)cc3)cc2C)c(C)c1] | 46000 |
| | 40 mol | |
| A8 | 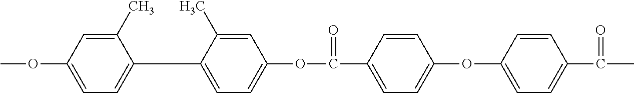 [SMILES: COc1ccc(Cc2ccc(OC(=O)c3ccc(Oc4ccc(C(C)=O)cc4)cc3)cc2C)c(C)c1] | 45000 |
| | 60 mol | |
| A9 | 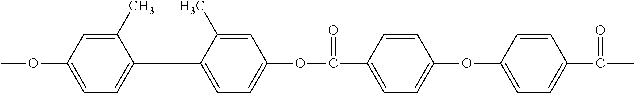 [SMILES: COc1ccc(Cc2ccc(OC(=O)c3ccc(Oc4ccc(C(C)=O)cc4)cc3)cc2C)c(C)c1] | 46000 |
| | 80 mol | |
| A10 | 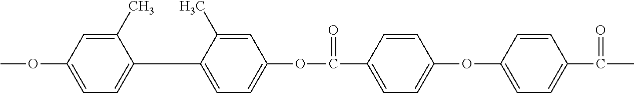 [SMILES: COc1ccc(Cc2ccc(OC(=O)c3ccc(Oc4ccc(C(C)=O)cc4)cc3)cc2C)c(C)c1] | 46000 |
| | 70 mol | |
| A11 | — | 46000 |
| | — | |
| A12 | — | 46000 |
| | — | |
| A13 | 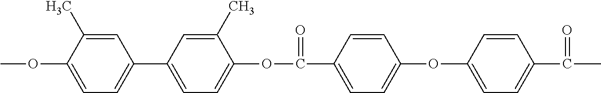 [SMILES: COc1ccc(-c2ccc(OC(=O)c3ccc(Oc4ccc(C(C)=O)cc4)cc3)c(C)c2)cc1C] | 46000 |
| | 40 mol | |
| A14 | 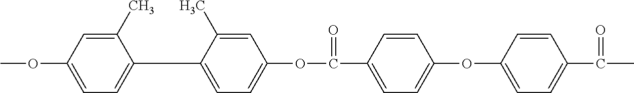 [SMILES: COc1ccc(Cc2ccc(OC(=O)c3ccc(Oc4ccc(C(C)=O)cc4)cc3)cc2C)c(C)c1] | 46000 |
| | 40 mol | |

### Production Example of Polycarbonate P1

677.00 g (2.52 mol) of the following structural formula (B-4), 360.36 g (1.68 mol) of the following structural formula (B-5), 0.4 g of triethylbenzylammonium chloride and 5.0 g of hydrosulfite were dissolved in 5.4 L of a 9.0 w/w % sodium hydroxide (NaOH) aqueous solution. 2.4 L of methylene chloride was added thereto, the components were held at 15° C. under stirring, and, subsequently, 540 g of phosgene was blown thereinto for 30 minutes. After the end of the blowing of phosgene, 21 g of p-t-butyl phenol was added thereto, the components were vigorously stirred to emulsify the reaction liquid, after the emulsification, 11 ml of triethylamine was added thereto, and the components were stirred at a temperature of 20° C. to 25° C. for approximately one hour and thereby polymerized.

After the end of the polymerization, the reaction liquid was separated into a water phase and an organic phase, and the organic phase was neutralized with phosphoric acid. The organic phase was repeatedly washed with water until the conductivity of the washing water reached 10 μS/cm or less. The obtained organic phase was added dropwise to warm water held at 62° C., and the solvent was evaporated and removed, thereby obtaining a white powdery precipitate. The obtained precipitate was filtered and dried at a temperature of 120° C. for 24 hours, thereby obtaining a target polycarbonate P1. The viscosity-average molecular weight of the obtained polycarbonate was 41,000.

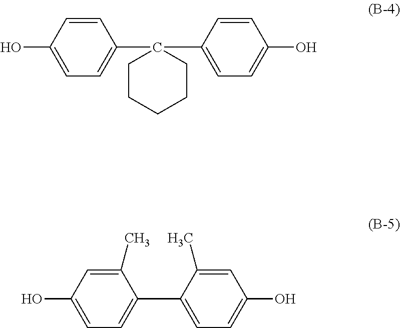 [SMILES: Oc1ccc(C2(c3ccc(O)cc3)CCCCC2)cc1 ; Cc1cc(O)ccc1-c1ccc(O)cc1C]

### Method for Measuring Viscosity-Average Molecular Weight

A resin that was a measurement object was dissolved in dichloromethane to prepare a solution having a concentration of 6.00 g/L. The specific viscosity at 25° C. was measured using an Ubbelohde viscometer. A limiting viscosity was obtained from this specific viscosity, and the viscosity-average molecular weight was calculated with K (proportional constant part) and a (index part; also indicated by α) of the Mark-Houwink viscosity equation set to 1.23×10⁻⁴ and 0.83, respectively.

### Production Examples of Polycarbonates P2 to P12

Polycarbonates were produced in the same manner as in the Production Example of the polycarbonate P1 except that, in the Production Example of the polycarbonate P1, structural units and rates were changed as shown in Table 3.

TABLE 3

| | | | | Molecular |
|---|---|---|---|---|
| | Configuration unit 1 | Configuration unit 2 | Configuration unit 3 | weight |
| P1 | 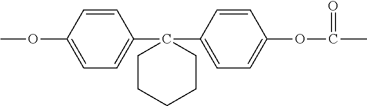 [SMILES: COc1ccc(C2(c3ccc(OC(C)=O)cc3)CCCCC2)cc1] | 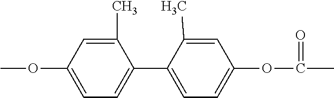 [SMILES: COc1ccc(-c2ccc(OC(C)=O)cc2C)c(C)c1] | — | 41000 |
| | 60 mol | 40 mol | — | |
| P2 | 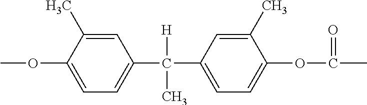 [SMILES: COc1ccc(C(C)c2ccc(OC(C)=O)c(C)c2)cc1C] | 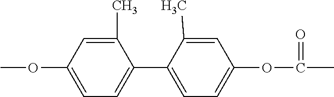 [SMILES: COc1ccc(-c2ccc(OC(C)=O)cc2C)c(C)c1] | — | 38000 |
| | 50 mol | 50 mol | — | |
| P3 | 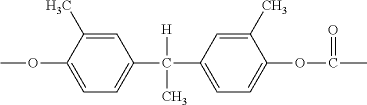 [SMILES: COc1ccc(C(C)c2ccc(OC(C)=O)c(C)c2)cc1C] | 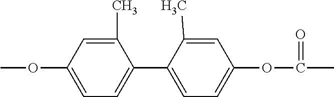 [SMILES: COc1ccc(-c2ccc(OC(C)=O)cc2C)c(C)c1] | — | 38000 |
| | 30 mol | 70 mol | — | |
| P4 | 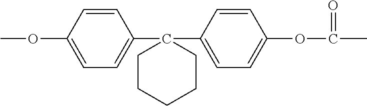 [SMILES: COc1ccc(C2(c3ccc(OC(C)=O)cc3)CCCCC2)cc1] | 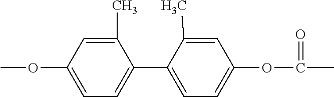 [SMILES: COc1ccc(-c2ccc(OC(C)=O)cc2C)c(C)c1] | 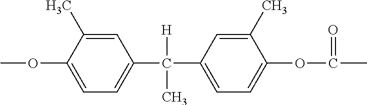 [SMILES: COc1ccc(C(C)c2ccc(OC(C)=O)c(C)c2)cc1C] | 37000 |
| | 20 mol | 60 mol | 20 mol | |
| P5 | 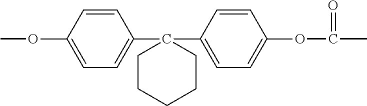 [SMILES: COc1ccc(C2(c3ccc(OC(C)=O)cc3)CCCCC2)cc1] | 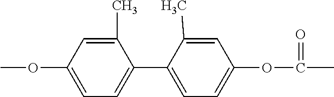 [SMILES: COc1ccc(-c2ccc(OC(C)=O)cc2C)c(C)c1] | 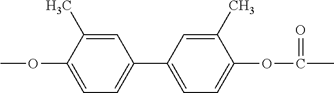 [SMILES: COc1ccc(-c2ccc(OC(C)=O)c(C)c2)cc1C] | 37000 |
| | 30 mol | 35 mol | 35 mol | |
| P6 | 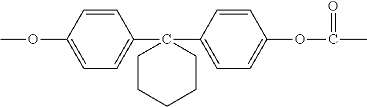 [SMILES: COc1ccc(C2(c3ccc(OC(C)=O)cc3)CCCCC2)cc1] | 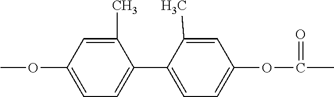 [SMILES: COc1ccc(-c2ccc(OC(C)=O)cc2C)c(C)c1] | 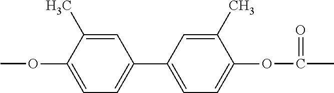 [SMILES: COc1ccc(-c2ccc(OC(C)=O)c(C)c2)cc1C] | 38000 |
| | 40 mol | 30 mol | 30 mol | |
| P7 | 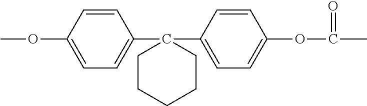 [SMILES: COc1ccc(C2(c3ccc(OC(C)=O)cc3)CCCCC2)cc1] | 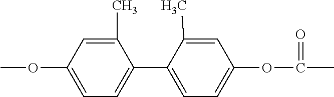 [SMILES: COc1ccc(-c2ccc(OC(C)=O)cc2C)c(C)c1] | 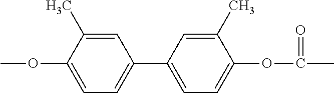 [SMILES: COc1ccc(-c2ccc(OC(C)=O)c(C)c2)cc1C] | 36000 |
| | 50 mol | 25 mol | 25 mol | |
| P8 | 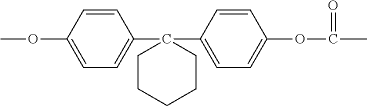 [SMILES: COc1ccc(C2(c3ccc(OC(C)=O)cc3)CCCCC2)cc1] | 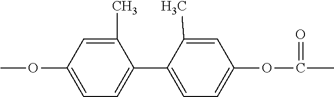 [SMILES: COc1ccc(-c2ccc(OC(C)=O)cc2C)c(C)c1] | 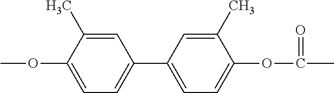 [SMILES: COc1ccc(-c2ccc(OC(C)=O)c(C)c2)cc1C] | 36000 |
| | 50 mol | 30 mol | 20 mol | |
| P9 | 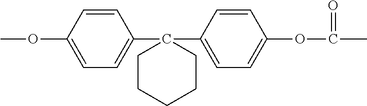 [SMILES: COc1ccc(C2(c3ccc(OC(C)=O)cc3)CCCCC2)cc1] | 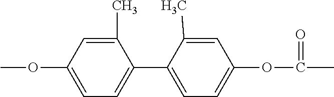 [SMILES: COc1ccc(-c2ccc(OC(C)=O)cc2C)c(C)c1] | 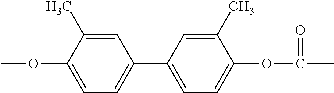 [SMILES: COc1ccc(-c2ccc(OC(C)=O)c(C)c2)cc1C] | 36000 |
| | 50 mol | 20 mol | 30 mol | |
| P10 | 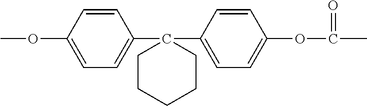 [SMILES: COc1ccc(C2(c3ccc(OC(C)=O)cc3)CCCCC2)cc1] | 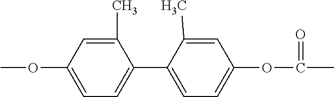 [SMILES: COc1ccc(-c2ccc(OC(C)=O)cc2C)c(C)c1] | 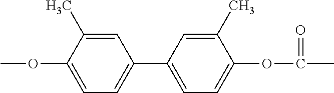 [SMILES: COc1ccc(-c2ccc(OC(C)=O)c(C)c2)cc1C] | 38000 |
| | 60 mol | 10 mol | 30 mol | |
| P11 | 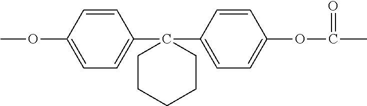 [SMILES: COc1ccc(C2(c3ccc(OC(C)=O)cc3)CCCCC2)cc1] | 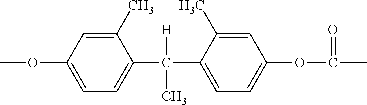 [SMILES: COc1ccc(C(C)c2ccc(OC(C)=O)cc2C)c(C)c1] | — | 40000 |
| | 70 mol | 30 mol | — | |
| P12 | 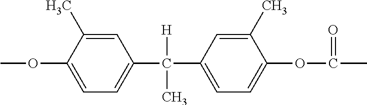 [SMILES: COc1ccc(C(C)c2ccc(OC(C)=O)c(C)c2)cc1C] | 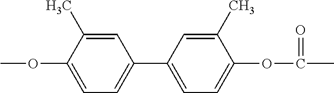 [SMILES: COc1ccc(-c2ccc(OC(C)=O)c(C)c2)cc1C] | — | 38000 |
| | 70 mol | 30 mol | — | |

### Example 1

### (Support)

A cylinder made of an aluminum alloy that was cut into 24 mm in outer diameter, 257 mm in length and 0.75 mm in thickness was used as a support.

### (Formation of Undercoat Layer)

A coating liquid for an undercoat layer was produced as described below. Surface-treated titanium oxide obtained by injecting rutile-type titanium oxide having an average primary particle diameter of 40 nm (“TTO55N” manufactured by Ishihara Sangyo Kaisha, Ltd.) and 3 mass % of methyldimethoxysilane (“TSL8117” manufactured by GE Toshiba Silicones Co., Ltd.) with respect to the titanium oxide into a high-speed fluidized mixing and kneading machine (“SMG300” manufactured by Kawata Mfg. Co., Ltd.) and mixing the components at a high speed of a rotation peripheral speed of 34.5 m/second was dispersed in methanol/1-propanol with a ball mill, thereby producing a dispersion slurry of hydrophobilized titanium oxide. The dispersion slurry, a solvent mixture of methanol/1-propanol/toluene and pellets of a copolymerized polyamide composed of ε-caprolactam [compound represented by the following formula (A)]/bis(4-amino-3-methylcyclohexyl)methane [compound represented by the following formula (B)]/hexamethylenediamine [compound represented by the following formula (C)]/decamethylene dicarboxylic acid [compound represented by the following formula (D)]/octadecamethylenedicarboxylic acid [compound represented by the following formula (E)] in a compositional mole ratios of 75%/9.5%/3%/9.5%/3% were stirred and mixed while being heated to dissolve the polyamide pellets, and then an ultrasonic dispersion treatment was performed thereon, thereby producing the coating liquid for an undercoat layer containing methanol, 1-propanol and toluene in a mass ratio of 7/1/2, containing hydrophobilized titanium oxide and the copolymerized polyamide in a mass ratio of 3/1 and having a solid content concentration of 18.0%. The support was dip-coated with this coating liquid for an undercoat layer to form a coating film, and the coating film was dried at 100° C. for 10 minutes, thereby forming a 2.00 μm undercoat layer.

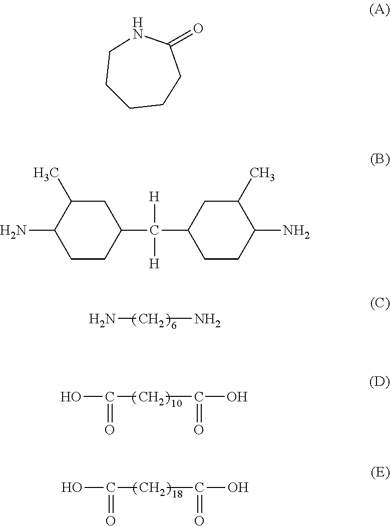

### (Formation of Charge Generation Layer)

As charge-generating substances, 10 parts of a Y-type oxytitanium phthalocyanine crystal having a strong peak at a Bragg angle (2θ±0.2°) of 27.3° in CuKα characteristic X-ray diffraction and 150 parts of 4-methoxy-4-methyl-2-pentanone were put into a sand mill in which glass beads having a diameter of 1 mm were used, pulverized and dispersed with a sand grind mill for 1.5 hours.

Next, 105 parts of a solution obtained by adding and dissolving 5 parts of a polyacetal resin (trade name: S-LEC B BX-1, manufactured by Sekisui Chemical Co., Ltd.) to and in 100 parts of 4-methoxy-4-methylpentanone-2 in advance was added thereto and dispersed therein for 0.5 hours.

After that, 250 parts of 1,2-dimethoxyethane was added thereto, thereby producing a coating liquid for a charge generation layer. The obtained undercoat layer was dip-coated with this coating liquid for a charge generation layer to form a coating film, and the coating film was dried at 100° C. for 10 minutes, thereby forming a 0.15 μm charge generation layer.

X-ray diffraction measurement was performed under the following conditions.

### Powder X-Ray Diffraction Measurement

Measuring instrument used: Manufactured by Rigaku Corporation, X-ray diffractometer RINT-TTRII
X-ray tube: Cu
Tube voltage: 50 kV
Tube current: 300 mA
Scanning method: 2θ/θ scanning
Scanning rate: 4.0°/min
Sampling interval: 0.02°
Start angle (2θ): 5.0°
Stop angle (2θ): 40.0°
Attachment: Standard sample holder
Filter: Not used
Incident monochromator: Used
Counter monochromator: Not used
Divergence slit: Open
Divergence longitudinal limiting slit: 10.00 mm
Scattering slit: Open
Receiving slit: Open
Flat plate monochromator: Used
Counter: Scintillation counter

### (Formation of Charge Transport Layer)

Next, a coating liquid for a charge transport layer was prepared by dissolving 6 parts of a charge transport substance indicated by CTM1, 7 parts of a polyarylate indicated by A1 and 3 parts of a polycarbonate indicated by P1 in a solvent mixture of 23 parts of orthoxylene, 23 parts of methyl benzoate and 23 parts of dimethoxymethane. The charge generation layer was dip-coated with this coating liquid for a charge transport layer to form a coating film, and the coating film was dried at 125° C. for 30 minutes, thereby forming a charge transport layer having a film thickness of 24 μm.

The results of pyrolysis GCMS of the resins in the surface layer of the obtained photosensitive member showed that a peak for which TIC had an MS spectrum where components with m/z=242 and m/z=227 were detected was present and a peak was present at 2.4 ppm in the ¹H-NMR spectrum, and thus it was specified that the formula (2-1) was included.

As an electrophotographic apparatus, a modified version of a laser beam printer manufactured by Hewlett-Packard Company with a trade name of HP Color Laser Jet Enterprise M653dn was used.

In the beginning, the electrophotographic apparatus and the produced electrophotographic photosensitive member were left to stand under an environment of a temperature of 15° C. and a humidity of 10% RH for 24 hours or more, then, the electrophotographic photosensitive member was mounted in a cyan-color cartridge of the electrophotographic apparatus and inserted into the main body.

After that, 100 half-tone images were printed, the cartridge was removed, and, among scratches present on the photosensitive member, only scratches deep enough to be visible to the eyes were counted. Furthermore, for the counted scratches, Rv, which indicates the maximum valley depth of each, was measured, and the maximum value is shown in Table 5.

After that, 40000 sheets with an image having a horizontal line such that the concentration became 1.5% per image were passed through, the cartridge was taken out, and, among scratches present on the photosensitive member, only scratches deep enough to be visible to the eyes were counted. Furthermore, for the counted scratches, Rvs' were measured, and the maximum value is shown in Table 5. When Rv exceeded 1.0 μm, there was a tendency that image damage occurred. The results are shown in Table 5.

Rv was measured under the following conditions.
Company name: Kosaka Laboratory Ltd.
Roughness meter name: SE3500
Cut-off value: 0.08 mm
Preliminary length: Cut-off×1
Filter characteristics: 2CR
Evaluation length: 2.5 mm
Vertical magnification: 10000
Horizontal magnification: 50
Feed length: 0.1 mm/sec
Leveling: Straight line (entire region)
JIS B 0601-1982
Treatment from entire length of evaluation length: Interval evaluation length is equally divided into 8000.
λs filter: None
Polarity: Normal

### Examples 2 to 73 and Comparative Examples 1 to 11

Photosensitive members were produced in the same manner as in Example 1 except that the photosensitive members were produced with a kind of polyarylate, a kind of polycarbonate, a kind of CTM, a binder rate and a CTM/binder rate shown in Table 4. The results are shown in Table 5.

### Example 74

7 parts of the polyarylate represented by A1 and 3 parts of the polycarbonate represented by P1 were dissolved in a solvent mixture of 23 parts of orthoxylene and 23 parts of methyl benzoate, and 1 part of a silica fine particle QSG-170 (manufactured by Shin-Etsu Chemical Co., Ltd., volume-average particle diameter: 170 nm) were added thereto and dispersed therein with a microfluidizer (M110-P manufactured by Powrex Corp.).

After that, as a charge transport layer, 8 parts of a charge transport substance represented by CTM3 and 23 parts of dimethoxymethane were added to and dissolved in the dispersion liquid, thereby preparing a coating liquid for a charge transport layer. The charge generation layer was dip-coated with this coating liquid for a charge transport layer to form a coating film, and the coating film was dried at 125° C. for 30 minutes, thereby forming a charge transport layer having a film thickness of 18 μm. The results are shown in Table 5.

### Example 75

A photosensitive member was produced in the same manner as in Example 74 except that, in Example 74, as a polycarbonate and a fine particle shown in Table 4, the fine particle was changed to a silica fine particle KE-S10 (Nippon Shokubai Co., Ltd., volume-average particle diameter: 0.1 μm). The results are shown in Table 5.

### Example 76

A photosensitive member was produced in the same manner as in Example 74 except that, in Example 74, as a polycarbonate and a fine particle shown in Table 4, the fine particle was changed to a silica fine particle KE-S30 (Nippon Shokubai Co., Ltd., volume-average particle diameter: 0.3 μm). The results are shown in Table 5.

### Example 77

A photosensitive member was produced in the same manner as in Example 74 except that, in Example 74, as a polycarbonate and a fine particle shown in Table 4, the fine particle was changed to a silica fine particle KE-P50 (Nippon Shokubai Co., Ltd., volume-average particle diameter: 0.5 μm). The results are shown in Table 5.

### Example 78

A photosensitive member was produced in the same manner as in Example 74 except that, in Example 74, as a polycarbonate and a fine particle shown in Table 4, the fine particle was changed to a silica fine particle 43-00-701 (Corefront Corp., volume-average particle diameter: 0.07 μm). The results are shown in Table 5.

### Example 79

A photosensitive member was produced in the same manner as in Example 74 except that, in Example 74, as a polycarbonate and a fine particle shown in Table 4, the fine particle was changed to a silica fine particle SO-C4 (Admatechs Korea Corporation, volume-average particle diameter: 0.9 to 1.2 μm). The results are shown in Table 5.

### Example 80

A photosensitive member was produced in the same manner as in Example 74 except that, in Example 74, as a polycarbonate and a fine particle shown in Table 4, the fine particle was changed to an alumina fine particle AKP-53 (Sumitomo Chemical Co., Ltd., volume-average particle diameter: 0.17 μm). The results are shown in Table 5.

### Example 81

A photosensitive member was produced in the same manner as in Example 74 except that, in Example 74, as a polycarbonate and a fine particle shown in Table 4, the fine particle was changed to a silica fine particle SO-C1 (Admatechs Korea Corporation, volume-average particle diameter: 0.2 to 0.4 μm). The results are shown in Table 5.

### Example 82

A photosensitive member was produced in the same manner as in Example 74 except that, in Example 74, as a polycarbonate and a fine particle shown in Table 4, the fine particle was changed to a silica fine particle QCB-100 (Shin-Etsu Chemical Co., Ltd., volume-average particle diameter: 0.2 μm). The results are shown in Table 5.

TABLE 4

| | | | | | | | Charge | | | | | | | |
|---|---|---|---|---|---|---|---|---|---|---|---|---|---|---|
| | | | | | | | transport | Formula | Formula | | | | | |
| | | | | Charge | Polyarylate | Polycarbonate | substance | (2-1) in | (2-1) in | Formula | Polyarylate | | Polycarbonate | |
| | | | Fine | transport | content | content | content | polyarylate/ | polycarbonate/ | (2-1) | | NMR/ | | NMR/ |
| | Polyarylate | Polycarbonate | particle | substance | ratio | ratio | ratio | mol | mol | mol/% | MS | ppm | MS | ppm |
| Example 1 | A1 | P1 | | CTM1 | 7 | 3 | 6 | | 40 | 7.5 | | | 227/242 | 2.4 |
| Example 2 | A1 | P1 | | CTM2 | 7 | 3 | 6 | | 40 | 7.5 | | | 227/242 | 2.4 |
| Example 3 | A1 | P1 | | CTM3 | 7 | 3 | 6 | | 40 | 7.5 | | | 227/242 | 2.4 |
| Example 4 | A1 | P1 | | CTM4 | 7 | 3 | 6 | | 40 | 7.5 | | | 227/242 | 2.4 |
| Example 5 | A1 | P1 | | CTM5 | 7 | 3 | 6 | | 40 | 7.5 | | | 227/242 | 2.4 |
| Example 6 | A1 | P1 | | CTM6 | 7 | 3 | 6 | | 40 | 7.5 | | | 227/242 | 2.4 |
| Example 7 | A1 | P1 | | CTM7 | 7 | 3 | 6 | | 40 | 7.5 | | | 227/242 | 2.4 |
| Example 8 | A1 | P1 | | CTM8 | 7 | 3 | 6 | | 40 | 7.5 | | | 227/242 | 2.4 |
| Example 9 | A1 | P1 | | CTM9 | 7 | 3 | 6 | | 40 | 7.5 | | | 227/242 | 2.4 |
| Example 10 | A1 | P1 | | CTM10 | 7 | 3 | 6 | | 40 | 7.5 | | | 227/242 | 2.4 |
| Example 11 | A1 | P1 | | CTM1 | 3 | 7 | 10 | | 40 | 14.0 | | | 227/242 | 2.4 |
| Example 12 | A1 | P1 | | CTM2 | 3 | 7 | 10 | | 40 | 14.0 | | | 227/242 | 2.4 |
| Example 13 | A1 | P1 | | CTM3 | 3 | 7 | 10 | | 40 | 14.0 | | | 227/242 | 2.4 |
| Example 14 | A1 | P4 | | CTM1 | 5 | 5 | 10 | | 60 | 15.0 | | | 227/242 | 2.4 |
| Example 15 | A1 | P4 | | CTM2 | 5 | 5 | 10 | | 60 | 15.0 | | | 227/242 | 2.4 |
| Example 16 | A1 | P4 | | CTM3 | 5 | 5 | 10 | | 60 | 15.0 | | | 227/242 | 2.4 |
| Example 17 | A1 | P2 | | CTM2 | 7 | 3 | 6 | | 50 | 9.4 | | | 227/242 | 2.4 |
| Example 18 | A1 | P3 | | CTM2 | 7 | 3 | 6 | | 70 | 13.1 | | | 227/242 | 2.4 |
| Example 19 | A1 | P4 | | CTM2 | 7 | 3 | 6 | | 60 | 11 | | | 227/242 | 2.4 |
| Example 20 | A1 | P5 | | CTM2 | 7 | 3 | 6 | | 35 | 7 | | | 227/242 | 2.4 |
| Example 21 | A1 | P6 | | CTM2 | 7 | 3 | 6 | | 30 | 6 | | | 227/242 | 2.4 |
| Example 22 | A1 | P7 | | CTM2 | 7 | 3 | 6 | | 25 | 5 | | | 227/242 | 2.4 |
| Example 23 | A1 | P8 | | CTM2 | 7 | 3 | 6 | | 30 | 6 | | | 227/242 | 2.4 |
| Example 24 | A1 | P9 | | CTM2 | 7 | 3 | 6 | | 20 | 4 | | | 227/242 | 2.4 |
| Example 25 | A1 | P10 | | CTM2 | 7 | 3 | 6 | | 10 | 2 | | | 227/242 | 2.4 |
| Example 26 | A2 | P1 | | CTM3 | 7 | 3 | 6 | | 40 | 8 | | | 227/242 | 2.4 |
| Example 27 | A2 | P2 | | CTM3 | 7 | 3 | 6 | | 50 | 9 | | | 227/242 | 2.4 |
| Example 28 | A2 | P3 | | CTM3 | 7 | 3 | 6 | | 70 | 13 | | | 227/242 | 2.4 |
| Example 29 | A2 | P4 | | CTM3 | 7 | 3 | 6 | | 60 | 11 | | | 227/242 | 2.4 |
| Example 30 | A2 | P5 | | CTM3 | 7 | 3 | 6 | | 35 | 7 | | | 227/242 | 2.4 |
| Example 31 | A2 | P6 | | CTM3 | 7 | 3 | 6 | | 30 | 6 | | | 227/242 | 2.4 |
| Example 32 | A2 | P7 | | CTM3 | 7 | 3 | 6 | | 25 | 5 | | | 227/242 | 2.4 |
| Example 33 | A2 | P8 | | CTM3 | 7 | 3 | 6 | | 30 | 6 | | | 227/242 | 2.4 |
| Example 34 | A2 | P9 | | CTM3 | 7 | 3 | 6 | | 20 | 4 | | | 227/242 | 2.4 |
| Example 35 | A2 | P10 | | CTM3 | 7 | 3 | 6 | | 10 | 2 | | | 227/242 | 2.4 |
| Example 36 | A3 | P1 | | CTM4 | 7 | 3 | 6 | | 40 | 8 | | | 227/242 | 2.4 |
| Example 37 | A3 | P2 | | CTM4 | 7 | 3 | 6 | | 50 | 9 | | | 227/242 | 2.4 |
| Example 38 | A3 | P3 | | CTM4 | 7 | 3 | 6 | | 70 | 13 | | | 227/242 | 2.4 |
| Example 39 | A3 | P4 | | CTM4 | 7 | 3 | 6 | | 60 | 11 | | | 227/242 | 2.4 |
| Example 40 | A3 | P5 | | CTM4 | 7 | 3 | 6 | | 35 | 7 | | | 227/242 | 2.4 |
| Example 41 | A3 | P6 | | CTM4 | 7 | 3 | 6 | | 30 | 6 | | | 227/242 | 2.4 |
| Example 42 | A3 | P7 | | CTM4 | 7 | 3 | 6 | | 25 | 5 | | | 227/242 | 2.4 |
| Example 43 | A3 | P8 | | CTM4 | 7 | 3 | 6 | | 30 | 6 | | | 227/242 | 2.4 |
| Example 44 | A3 | P9 | | CTM4 | 7 | 3 | 6 | | 20 | 4 | | | 227/242 | 2.4 |
| Example 45 | A3 | P10 | | CTM4 | 7 | 3 | 6 | | 10 | 2 | | | 227/242 | 2.4 |
| Example 46 | A6 | P1 | | CTM2 | 5 | 5 | 6 | 50 | 40 | 28 | 227/242 | 2.35/2.4 | 227/242 | 2.4 |
| Example 47 | A6 | P2 | | CTM2 | 5 | 5 | 6 | 50 | 50 | 31 | 227/242 | 2.35/2.4 | 227/242 | 2.4 |
| Example 48 | A6 | P3 | | CTM2 | 5 | 5 | 6 | 50 | 70 | 38 | 227/242 | 2.35/2.4 | 227/242 | 2.4 |
| Example 49 | A6 | P4 | | CTM2 | 5 | 5 | 6 | 50 | 60 | 34 | 227/242 | 2.35/2.4 | 227/242 | 2.4 |
| Example 50 | A6 | P5 | | CTM2 | 5 | 5 | 6 | 50 | 35 | 27 | 227/242 | 2.35/2.4 | 227/242 | 2.4 |
| Example 51 | A6 | P6 | | CTM2 | 5 | 5 | 6 | 50 | 30 | 25 | 227/242 | 2.35/2.4 | 227/242 | 2.4 |
| Example 52 | A6 | P7 | | CTM2 | 5 | 5 | 6 | 50 | 25 | 23 | 227/242 | 2.35/2.4 | 227/242 | 2.4 |
| Example 53 | A6 | P8 | | CTM2 | 5 | 5 | 6 | 50 | 30 | 25 | 227/242 | 2.35/2.4 | 227/242 | 2.4 |
| Example 54 | A6 | P9 | | CTM2 | 5 | 5 | 6 | 50 | 20 | 22 | 227/242 | 2.35/2.4 | 227/242 | 2.4 |
| Example 55 | A6 | P10 | | CTM2 | 5 | 5 | 6 | 50 | 10 | 19 | 227/242 | 2.35/2.4 | 227/242 | 2.4 |
| Example 56 | A8 | P1 | | CTM3 | 7 | 3 | 6 | 60 | 40 | 34 | 227/242 | 2.35/2.4 | 227/242 | 2.4 |
| Example 57 | A8 | P2 | | CTM3 | 7 | 3 | 6 | 60 | 50 | 36 | 227/242 | 2.35/2.4 | 227/242 | 2.4 |
| Example 58 | A8 | P3 | | CTM3 | 7 | 3 | 6 | 60 | 70 | 39 | 227/242 | 2.35/2.4 | 227/242 | 2.4 |
| Example 59 | A8 | P4 | | CTM3 | 7 | 3 | 6 | 60 | 60 | 38 | 227/242 | 2.35/2.4 | 227/242 | 2.4 |
| Example 60 | A8 | P5 | | CTM3 | 7 | 3 | 6 | 60 | 35 | 33 | 227/242 | 2.35/2.4 | 227/242 | 2.4 |
| Example 61 | A8 | P6 | | CTM3 | 7 | 3 | 6 | 60 | 30 | 32 | 227/242 | 2.35/2.4 | 227/242 | 2.4 |
| Example 62 | A8 | P7 | | CTM3 | 7 | 3 | 6 | 60 | 25 | 31 | 227/242 | 2.35/2.4 | 227/242 | 2.4 |
| Example 63 | A8 | P8 | | CTM3 | 7 | 3 | 6 | 60 | 30 | 32 | 227/242 | 2.35/2.4 | 227/242 | 2.4 |
| Example 64 | A8 | P9 | | CTM3 | 7 | 3 | 6 | 60 | 20 | 30 | 227/242 | 2.35/2.4 | 227/242 | 2.4 |
| Example 65 | A8 | P10 | | CTM3 | 7 | 3 | 6 | 60 | 10 | 28 | 227/242 | 2.35/2.4 | 227/242 | 2.4 |
| Example 66 | A1 | P6 | | CTM2 | 3 | 7 | 6 | | 30 | 13 | | | 227/242 | 2.4 |
| Example 67 | A8 | P3 | | CTM3 | 3 | 7 | 6 | 60 | 70 | 42 | 227/242 | 2.35/2.4 | 227/242 | 2.4 |
| Example 68 | A8 | P3 | | CTM3 | 3 | 7 | 6 | 60 | 70 | 42 | 227/242 | 2.35/2.4 | 227/242 | 2.4 |
| Example 69 | A4 | P7 | | CTM4 | 7 | 3 | 8 | | 25 | 4 | | | 227/242 | 2.4 |
| Example 70 | A5 | P7 | | CTM4 | 7 | 3 | 8 | | 25 | 4 | | | 227/242 | 2.4 |
| Example 71 | A7 | P7 | | CTM4 | 7 | 3 | 8 | 40 | 25 | 20 | 227/242 | 2.35/2.4 | 227/242 | 2.4 |
| Example 72 | A9 | P7 | | CTM4 | 7 | 3 | 8 | 80 | 25 | 35 | 227/242 | 2.35/2.4 | 227/242 | 2.4 |
| Example 73 | A10 | P5 | | CTM3 | 7 | 3 | 8 | 70 | 35 | 33 | 227/242 | 2.35/2.4 | 227/242 | 2.4 |
| Example 74 | A1 | P1 | Silica | CTM3 | 7 | 3 | 8 | | 40 | 7 | | | 227/242 | 2.4 |
| | | | fine | | | | | | | | | | | |
| | | | particle | | | | | | | | | | | |
| Example 75 | A1 | P2 | Silica | CTM3 | 7 | 3 | 8 | | 50 | 8 | | | 227/242 | 2.4 |
| | | | fine | | | | | | | | | | | |
| | | | particle | | | | | | | | | | | |
| Example 76 | A1 | P4 | Silica | CTM3 | 7 | 3 | 8 | | 60 | 10 | | | 227/242 | 2.4 |
| | | | fine | | | | | | | | | | | |
| | | | particle | | | | | | | | | | | |
| Example 77 | A1 | P5 | Silica | CTM3 | 7 | 3 | 8 | | 35 | 6 | | | 227/242 | 2.4 |
| | | | fine | | | | | | | | | | | |
| | | | particle | | | | | | | | | | | |
| Example 78 | A1 | P6 | Silica | CTM3 | 7 | 3 | 8 | | 30 | 5 | | | 227/242 | 2.4 |
| | | | fine | | | | | | | | | | | |
| | | | particle | | | | | | | | | | | |
| Example 79 | A1 | P6 | Silica | CTM3 | 7 | 3 | 8 | | 30 | 5 | | | 227/242 | 2.4 |
| | | | fine | | | | | | | | | | | |
| | | | particle | | | | | | | | | | | |
| Example 80 | A1 | P6 | Alumina | CTM3 | 7 | 3 | 8 | | 30 | 5 | | | 227/242 | 2.4 |
| | | | fine | | | | | | | | | | | |
| | | | particle | | | | | | | | | | | |
| Example 81 | A1 | P6 | Silica | CTM3 | 7 | 3 | 8 | | 30 | 5 | | | 227/242 | 2.4 |
| | | | fine | | | | | | | | | | | |
| | | | particle | | | | | | | | | | | |
| Example 82 | A1 | P10 | Silica | CTM3 | 7 | 3 | 8 | | 10 | 2 | | | 227/242 | 2.4 |
| | | | fine | | | | | | | | | | | |
| | | | particle | | | | | | | | | | | |
| Comparative | A1 | | | CTM3 | 10 | | 6 | | | 0 | | | | |
| Example 1 | | | | | | | | | | | | | | |
| Comparative | A2 | | | CTM3 | 10 | | 6 | | | 0 | | | | |
| Example 2 | | | | | | | | | | | | | | |
| Comparative | A5 | | | CTM3 | 10 | | 6 | | | 0 | | | | |
| Example 3 | | | | | | | | | | | | | | |
| Comparative | | P1 | | CTM3 | | 10 | 6 | | 40 | 25 | | | 227/242 | 2.4 |
| Example 4 | | | | | | | | | | | | | | |
| Comparative | A1 | P11 | | CTM3 | 6 | 4 | 6 | | | 0 | | | | |
| Example 5 | | | | | | | | | | | | | | |
| Comparative | A7 | P12 | | CTM3 | 6 | 4 | 6 | 40 | | 15 | 227/242 | 2.35/2.4 | 227/242 | |
| Example 6 | | | | | | | | | | | | | | |
| Comparative | A11 | P1 | | CTM3 | 7 | 3 | 6 | | 40 | 8 | | | 227/242 | 2.4 |
| Example 7 | | | | | | | | | | | | | | |
| Comparative | A12 | P1 | | CTM3 | 7 | 3 | 6 | | 40 | 8 | | | 227/242 | 2.4 |
| Example 8 | | | | | | | | | | | | | | |
| Comparative | A13 | P1 | | CTM3 | 7 | 3 | 6 | | 40 | 8 | 227/242 | 2.35 | 227/242 | 2.4 |
| Example 9 | | | | | | | | | | | | | | |
| Comparative | A14 | P1 | | CTM3 | 7 | 3 | 6 | 40 | 40 | 25 | 227/242 | 2.4 | 227/242 | 2.4 |
| Example 10 | | | | | | | | | | | | | | |
| Comparative | | P12 | | CTM3 | | 10 | 6 | | | 0 | | | 227/242 | |
| Example 11 | | | | | | | | | | | | | | |

TABLE 5

| | Number of | | Number of | |
|---|---|---|---|---|
| | initial | Initial | scratches after | Endurance |
| | scratches | Rv | endurance | Rv |
| Example 1 | 1 | 0.1 | 7 | 0.4 |
| Example 2 | 0 | — | 6 | 0.4 |
| Example 3 | 0 | — | 6 | 0.4 |
| Example 4 | 0 | — | 6 | 0.4 |
| Example 5 | 1 | 0.1 | 7 | 0.4 |
| Example 6 | 1 | 0.1 | 7 | 0.4 |
| Example 7 | 1 | 0.1 | 7 | 0.4 |
| Example 8 | 1 | 0.1 | 7 | 0.4 |
| Example 9 | 1 | 0.1 | 7 | 0.4 |
| Example 10 | 1 | 0.1 | 7 | 0.4 |
| Example 11 | 1 | 0.1 | 7 | 0.4 |
| Example 12 | 0 | — | 6 | 0.4 |
| Example 13 | 0 | — | 6 | 0.4 |
| Example 14 | 1 | 0.1 | 7 | 0.4 |
| Example 15 | 0 | — | 6 | 0.4 |
| Example 16 | 0 | — | 6 | 0.4 |
| Example 17 | 0 | — | 6 | 0.4 |
| Example 18 | 1 | 0.1 | 7 | 0.4 |
| Example 19 | 0 | — | 6 | 0.4 |
| Example 20 | 0 | — | 4 | 0.3 |
| Example 21 | 1 | 0.1 | 4 | 0.3 |
| Example 22 | 1 | 0.1 | 6 | 0.4 |
| Example 23 | 0 | — | 4 | 0.3 |
| Example 24 | 1 | 0.1 | 6 | 0.4 |
| Example 25 | 2 | 0.1 | 7 | 0.4 |
| Example 26 | 0 | — | 6 | 0.4 |
| Example 27 | 0 | — | 6 | 0.4 |
| Example 28 | 1 | 0.1 | 7 | 0.4 |
| Example 29 | 0 | — | 6 | 0.4 |
| Example 30 | 0 | — | 4 | 0.3 |
| Example 31 | 0 | — | 4 | 0.3 |
| Example 32 | 1 | 0.1 | 6 | 0.4 |
| Example 33 | 0 | — | 4 | 0.3 |
| Example 34 | 1 | 0.1 | 6 | 0.4 |
| Example 35 | 1 | 0.1 | 7 | 0.4 |
| Example 36 | 0 | — | 6 | 0.4 |
| Example 37 | 0 | — | 6 | 0.4 |
| Example 38 | 1 | 0.1 | 7 | 0.4 |
| Example 39 | 0 | — | 6 | 0.4 |
| Example 40 | 0 | — | 4 | 0.3 |
| Example 41 | 0 | — | 4 | 0.3 |
| Example 42 | 1 | 0.1 | 6 | 0.4 |
| Example 43 | 0 | — | 4 | 0.3 |
| Example 44 | 1 | 0.1 | 6 | 0.4 |
| Example 45 | 1 | 0.1 | 7 | 0.4 |
| Example 46 | 0 | — | 6 | 0.4 |
| Example 47 | 0 | — | 6 | 0.4 |
| Example 48 | 1 | 0.1 | 7 | 0.4 |
| Example 49 | 0 | — | 6 | 0.4 |
| Example 50 | 0 | — | 4 | 0.4 |
| Example 51 | 0 | — | 4 | 0.4 |
| Example 52 | 0 | — | 4 | 0.4 |
| Example 53 | 0 | — | 4 | 0.4 |
| Example 54 | 0 | — | 4 | 0.4 |
| Example 55 | 1 | 0.1 | 5 | 0.4 |
| Example 56 | 0 | — | 5 | 0.4 |
| Example 57 | 0 | — | 5 | 0.4 |
| Example 58 | 1 | 0.1 | 7 | 0.4 |
| Example 59 | 0 | — | 5 | 0.4 |
| Example 60 | 0 | — | 5 | 0.3 |
| Example 61 | 0 | — | 5 | 0.3 |
| Example 62 | 0 | — | 5 | 0.3 |
| Example 63 | 0 | — | 5 | 0.3 |
| Example 64 | 0 | — | 5 | 0.3 |
| Example 65 | 1 | 0.1 | 5 | 0.4 |
| Example 66 | 0 | — | 5 | 0.3 |
| Example 67 | 1 | 0.1 | 8 | 0.5 |
| Example 68 | 0 | — | 8 | 0.5 |
| Example 69 | 1 | 0.1 | 6 | 0.4 |
| Example 70 | 1 | 0.1 | 6 | 0.4 |
| Example 71 | 0 | — | 5 | 0.3 |
| Example 72 | 0 | — | 5 | 0.3 |
| Example 73 | 0 | — | 5 | 0.3 |
| Example 74 | 0 | — | 4 | 0.3 |
| Example 75 | 0 | — | 4 | 0.3 |
| Example 76 | 0 | — | 4 | 0.3 |
| Example 77 | 0 | — | 3 | 0.2 |
| Example 78 | 0 | — | 3 | 0.3 |
| Example 79 | 0 | — | 3 | 0.3 |
| Example 80 | 0 | — | 3 | 0.3 |
| Example 81 | 0 | — | 3 | 0.2 |
| Example 82 | 0 | — | 5 | 0.3 |
| Comparative Example 1 | 2 | 0.2 | 10 | 1.1 |
| Comparative Example 2 | 2 | 0.2 | 12 | 1.1 |
| Comparative Example 3 | 2 | 0.2 | 14 | 1.1 |
| Comparative Example 4 | 1 | 0.2 | 12 | 1.2 |
| Comparative Example 5 | 2 | 0.2 | 14 | 1.0 |
| Comparative Example 6 | 2 | 0.2 | 13 | 1.0 |
| Comparative Example 7 | 2 | 0.1 | 14 | 1.1 |
| Comparative Example 8 | 2 | 0.1 | 14 | 1.1 |
| Comparative Example 9 | 2 | 0.1 | 14 | 1.0 |
| Comparative Example 10 | 2 | 0.1 | 13 | 1.0 |
| Comparative Example 11 | 2 | 0.1 | 14 | 1.1 |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-188615, filed Nov. 25, 2022, which is hereby incorporated by reference herein in its entirety.

What is claimed is:

1. An electrophotographic photosensitive member comprising:
a surface layer comprising a polyarylate and a polycarbonate,
wherein the polyarylate has at least one structural unit selected from the group consisting of a structural unit represented by the following formula (1-1), a structural unit represented by the following formula (1-2) and a structural unit represented by the following formula (1-3), and
the polycarbonate has a structural unit represented by the following formula (2-1),

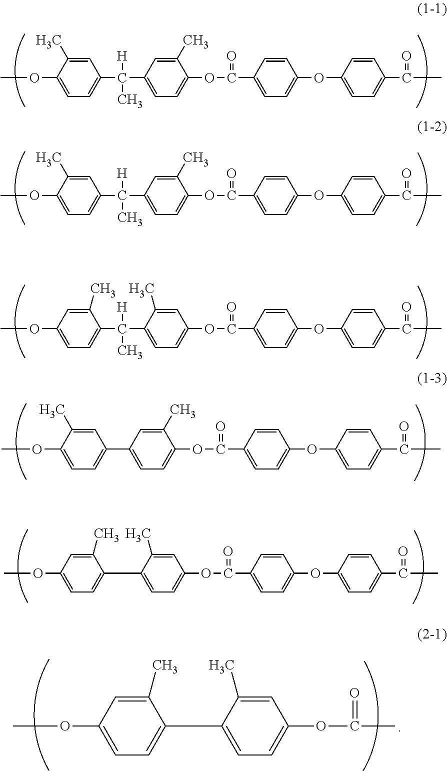

2. The electrophotographic photosensitive member according to claim 1, wherein the surface layer comprises 5 mol % to 40 mol % of the structural unit represented by the formula (2-1).

3. The electrophotographic photosensitive member according to claim 1, wherein the polycarbonate comprises 20 mol % to 60 mol % of the structural unit represented by the formula (2-1).

4. An electrophotographic photosensitive member comprising:
a surface layer comprising a polyarylate and a polycarbonate,
wherein, in a component analysis of a polymer component collected from the surface layer,
the polyarylate
has a peak for which TIC has an MS spectrum where components with m/z=242 and m/z=227 are detected in pyrolysis gas chromatography-mass spectrometry under the coexistence of TMAH and
has peaks at 2.40±0.02 ppm and 2.35±0.02 ppm in a ¹H-NMR spectrum for which heavy chloroform is used, and
the polycarbonate
has a peak for which TIC has an MS spectrum where components with m/z=242 and m/z=227 are detected in pyrolysis gas chromatography-mass spectrometry under the coexistence of TMAH and
has a peak at 2.40±0.02 ppm in a ¹H-NMR spectrum for which heavy chloroform is used.

5. The electrophotographic photosensitive member according to claim 1, wherein the surface layer comprises a silica fine particle.

6. The electrophotographic photosensitive member according to claim 5, wherein the silica fine particle has a volume-average particle diameter of 0.1 μm to 0.5 μm.

7. A process cartridge that integrally supports an electrophotographic photosensitive member and at least one unit selected from the group consisting of a charging unit, a developing unit and a cleaning unit and is detachably attachable to a main body of an electrophotographic apparatus, wherein the electrophotographic photosensitive member has a surface layer comprising a polyarylate and a polycarbonate,
wherein the polyarylate has at least one structural unit selected from the group consisting of a structural unit represented by the following formula (1-1), a structural unit represented by the following formula (1-2) and a structural unit represented by the following formula (1-3), and
wherein the polycarbonate has a structural unit represented by the following formula (2-1),

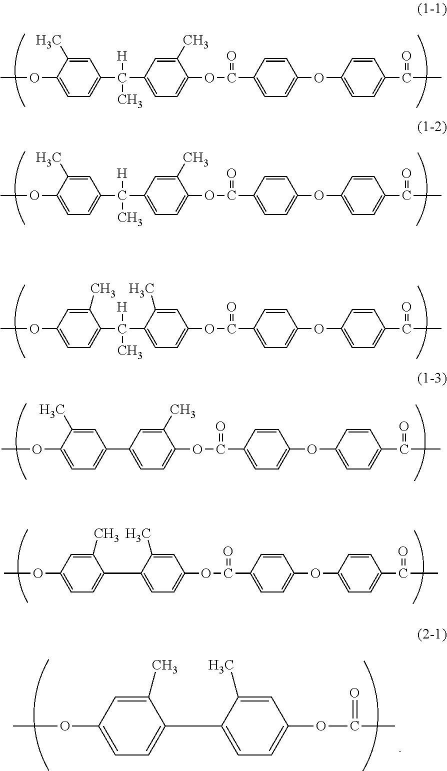

8. A process cartridge that integrally supports an electrophotographic photosensitive member and at least one unit selected from the group consisting of a charging unit, a developing unit and a cleaning unit and is detachably attachable to a main body of an electrophotographic apparatus, wherein the electrophotographic photosensitive member has a surface layer comprising a polyarylate and a polycarbonate,
wherein in a component analysis of a polymer component collected from the surface layer,
the polyarylate
has a peak for which TIC has an MS spectrum where components with m/z=242 and m/z=227 are detected in pyrolysis gas chromatography-mass spectrometry under the coexistence of TMAH and
has peaks at 2.40±0.02 ppm and 2.35±0.02 ppm in a ¹H-NMR spectrum for which heavy chloroform is used, and
the polycarbonate
has a peak for which TIC has an MS spectrum where components with m/z=242 and m/z=227 are detected in pyrolysis gas chromatography-mass spectrometry under the coexistence of TMAH and
has a peak at 2.40±0.02 ppm in a ¹H-NMR spectrum for which heavy chloroform is used.

9. An electrophotographic apparatus comprising:
an electrophotographic photosensitive member;
a charging unit;
an exposure unit;
a developing unit; and
a transfer unit,
wherein the electrophotographic photosensitive member has a surface layer comprising a polyarylate and a polycarbonate,
wherein the polyarylate has at least one structural unit selected from the group consisting of a structural unit represented by the following formula (1-1), a structural unit represented by the following formula (1-2) and a structural unit represented by the following formula (1-3), and
wherein the polycarbonate has a structural unit represented by the following formula (2-1),

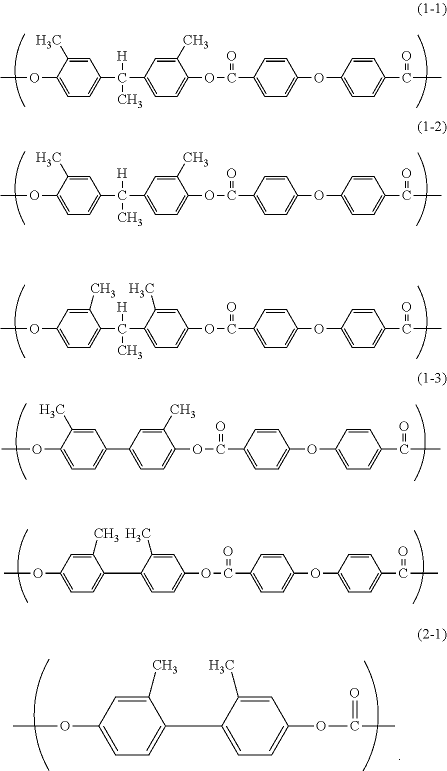

10. An electrophotographic apparatus comprising:
an electrophotographic photosensitive member;
a charging unit;
an exposure unit;
a developing unit; and
a transfer unit,
wherein the electrophotographic photosensitive member has a surface layer comprising a polyarylate and a polycarbonate,
wherein in a component analysis of a polymer component collected from the surface layer,
the polyarylate
has a peak for which TIC has an MS spectrum where components with m/z=242 and m/z=227 are detected in pyrolysis gas chromatography-mass spectrometry under the coexistence of TMAH and
has peaks at 2.40±0.02 ppm and 2.35±0.02 ppm in a ¹H-NMR spectrum for which heavy chloroform is used, and
the polycarbonate
has a peak for which TIC has an MS spectrum where components with m/z=242 and m/z=227 are detected in pyrolysis gas chromatography-mass spectrometry under the coexistence of TMAH and
has a peak at 2.40±0.02 ppm in a ¹H-NMR spectrum for which heavy chloroform is used.
